(19) United States
(12) Patent Application Publication
(10) Pub. No.: US 2025/0390025 A1
(43) Pub. Date: Dec. 25, 2025

(54) OPTIMAL NEAR-FIELD GENERATION METHOD AND MASK MANUFACTURING METHOD COMPRISING THE SAME

(71) Applicant: Samsung Electronics Co., Ltd., Suwon-si (KR)

(72) Inventors: Minho KIM, Suwon-si (KR); Doyun KIM, Suwon-si (KR); Useong KIM, Suwon-si (KR); Kyoungyoon PARK, Suwon-si (KR)

(73) Assignee: Samsung Electronics Co., Ltd., Suwon-si (KR)

(21) Appl. No.: 19/011,972

(22) Filed: Jan. 7, 2025

(30) Foreign Application Priority Data
Jun. 25, 2024 (KR) 10-2024-0083038

(51) Int. Cl. G03F 7/00

(52) U.S. Cl. CPC G03F 7/70325; G03F 7/0037; G03F 7/706837; G03F 7/706841

(57) ABSTRACT

Provided are an optimal near-field generation method and a mask manufacturing method comprising the optimal near-field generation method. The optimal near-field generation method may include obtaining a mutual interference complex diffraction pattern formed by mutual interference between a plurality of spherical waves formed as a certain plane wave incident on each of a plurality of edge segments differentiated from an edge of a design layout is scattered on each of the plurality of edge segments, obtaining a complex near-field by applying a Kirchhoff boundary condition to the mutual interference complex diffraction pattern, and obtaining an optimal near-field by optimizing the complex near-field so as to reduce a difference between the complex near-field and a rigorous near-field of the design layout.

### CROSS-REFERENCE TO RELATED APPLICATION

This application is based on and claims priority under 35 U.S.C. § 119 to Korean Patent Application No. 10-2024-0083038, filed on Jun. 25, 2024, in the Korean Intellectual Property Office, the disclosure of which is incorporated by reference herein in its entirety.

### BACKGROUND

The inventive concepts relate to a mask manufacturing method, and more particularly, to an optimal near-field generation method and a mask manufacturing method comprising the optimal near-field generation method.

In a semiconductor process, a photolithography process using a mask may be performed to form a pattern on a semiconductor substrate such as a wafer. Briefly, a mask may be referred to as a pattern transfer body, and may include a pattern shape of an opaque material formed on a base layer material configured to transfer a corresponding pattern onto a substrate.

In a brief description of a mask manufacturing process, first, a circuit is designed and a layout for the circuit is designed, and then, design data obtained through optical proximity correction (OPC) is transmitted as mask tape-out (MTO) design data. Then, mask data preparation (MDP) is performed based on the MTO design data, and an exposure process or the like may be performed on a mask substrate.

### SUMMARY

The inventive concept provides an optimal near-field generation method which may prevent (and/or mitigate the potential for) overfitting and quickly generate a near-field, and a mask manufacturing method comprising the optimal near-field generation method.

Furthermore, the technical objectives to be achieved by the disclosure are not limited to the above-described objectives, and other technical objectives that are not mentioned herein would be clearly understood by a person skilled in the art from the description of the disclosure.

According to an aspect of the inventive concepts, there is provided an optimal near-field generation method including obtaining a mutual interference complex diffraction pattern of a design layout for a target pattern, the mutual interference complex diffraction pattern representing a pattern formed by mutual interference between a plurality of spherical waves formed as a plane wave incident at an angle with respect to each of a plurality of edge segments of the design layout is scattered on each of the plurality of edge segments, obtaining a complex near-field by reflecting, to the mutual interference complex diffraction pattern, a mask three-dimensional (3D) effect that changes depending on a direction in which the plane wave is incident to the plurality of edge segments, and obtaining an optimal near-field by reducing a difference between the complex near-field and a rigorous near-field of the design layout using an artificial neural network.

According to another aspect of the inventive concepts, there is provided an optimal near-field generation method including obtaining a mutual interference complex diffraction pattern of a design layout for a target pattern, the mutual interference complex diffraction pattern representing a pattern formed by mutual interference between a plurality of spherical waves formed as a plane wave incident at an angle with respect to each of a plurality of edge segments of the design layout is scattered on each of the plurality of edge segments, obtaining a complex near-field by reflecting, to the mutual interference complex diffraction pattern, a mask three-dimensional (3D) effect that changes depending on a direction in which the plane wave is incident to the plurality of edge segments, obtaining a corrected near-field generation by correcting the complex near-field using a Volterra series on an error, the error based on a difference between the complex near-field and a rigorous near-field of the design layout, and obtaining an optimal near-field by reducing a difference between the complex near-field and the rigorous near-field of the design layout using an artificial neural network.

According to another aspect of the inventive concepts, there is provided a mask manufacturing method including receiving an input of a design layout for a target pattern, converting the design layout into a binary layout, extracting an edge of the binary layout, forming a plurality of edge segments by differentiating the edge, obtaining a first complex diffraction pattern, the first complex diffraction pattern representing a pattern formed by a spherical wave formed as a plane wave incident at an angle with respect to the plurality of edge segments is scattered on the plurality of edge segments, obtaining a mutual interference complex diffraction pattern, the mutual interference complex diffraction pattern representing a pattern formed by mutual interference between the first complex diffraction patterns, obtaining a complex near-field by reflecting, to the mutual interference complex diffraction pattern, a mask three-dimensional (3D) effect that changes depending on a direction in which the plane wave is incident to the plurality of edge segments, obtaining a corrected near-field by correcting an error, the error based on a difference between the complex near-field and a rigorous near-field of the design layout, obtaining an optimal near-field by optimizing the corrected near-field so as to reduce a difference between the corrected near-field and the rigorous near-field of the design layout, generating an optical proximity correction (OPC) model based on the optimal near-field, obtaining an OPC-ed design layout by performing a simulation using an OPC model, transmitting data about the OPC-ed layout as mask tape-out (MTO) design data, preparing mask data based on the MTO design data, and exposing a substrate for a mask based on the mask data.

### BRIEF DESCRIPTION OF THE DRAWINGS

Embodiments will be more clearly understood from the following detailed description taken in conjunction with the accompanying drawings in which:

FIG. 1 is a flowchart schematically showing an optimal near-field generation method according to at least one embodiment;

FIG. 2 is a flowchart schematically showing an example of the mutual interference complex diffraction pattern generation operation of FIG. 1;

FIG. 3A is an image showing a design layout;

FIG. 3B is an image showing a binary layout;

FIGS. 4A and 4B are images showing a mutual interference complex diffraction pattern;

FIG. 5 is a flowchart schematically showing an example of a complex near-field generation operation of FIG. 1;

FIG. 6A is an image showing a blurred binary layout generation operation of FIG. 5;

FIG. 6B is an image showing a complex near-field generation operation of FIG. 5;

FIG. 7 is a configuration view schematically showing an artificial neural network used for optimal near-field generation;

FIG. 8 is a flowchart schematically showing an optimal near-field generation method according to another embodiment;

FIG. 9 is a flowchart schematically showing an example of a mutual interference complex diffraction pattern generation operation of FIG. 8;

FIG. 10 is a flowchart schematically showing an example of a complex near-field generation operation of FIG. 8;

FIG. 11 is a flowchart schematically showing an example of a corrected near-field generation operation of FIG. 8;

FIG. 12A is an image showing an x component of a normal vector field for an edge of a pattern within a design layout;

FIG. 12B is an image showing a y component of a normal vector field for an edge of a pattern within a design layout;

FIG. 12C is an image showing a level set of a pattern within a design layout;

FIGS. 12D to 12G are images showing features of a pattern within a design layout;

FIGS. 13A to 13D are images showing a linear error corrected feature;

FIG. 13E is an image showing a sum of the linear error corrected features of FIGS. 13A to 13D;

FIG. 14 is a flowchart schematically showing another example of a corrected near-field generation operation of FIG. 8;

FIG. 15A includes images showing non-linear error corrected features;

FIG. 15B is an image showing a sum of self-coupled non-linear error corrected features;

FIG. 15C is an image showing a sum of mutually coupled non-linear error corrected features;

FIG. 16 is an image showing a rigorous near-field, a complex near-field, and a difference between the rigorous near-field and the complex near-field;

FIG. 17 is an image showing a rigorous near-field, a linearly corrected near-field, and a difference between the rigorous near-field and the linearly corrected near-field;

FIG. 18 is an image showing a rigorous near-field, a self-coupled non-linearly corrected near-field, and a difference between the rigorous near-field and the self-coupled non-linearly corrected near-field;

FIG. 19 is an image showing a rigorous near-field, a mutually coupled non-linearly corrected near-field, and a difference between the rigorous near-field and the mutually coupled non-linearly corrected near-field;

FIG. 20A includes images showing optimal near-fields for patterns of various shapes formed according to an optimal near-field generation method according to at least one embodiment;

FIG. 20B includes images showing rigorous near-fields for patterns of various shapes;

FIG. 21 is a flowchart schematically showing an optical proximity correction (OPC) method according to at least one embodiment;

FIG. 22 is a flowchart schematically showing an OPC model generation operation of FIG. 21; and

FIG. 23 is a flowchart schematically showing a process of a mask manufacturing method including the OPC method according to at least one embodiment.

### DETAILED DESCRIPTION OF THE EMBODIMENTS

Embodiments of the inventive concepts are described below in detail with reference to the accompanying drawings. Throughout the drawings, like reference numerals indicate like elements, and redundant descriptions thereof are omitted. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

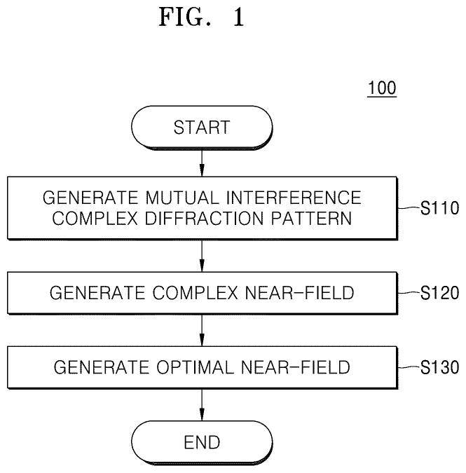

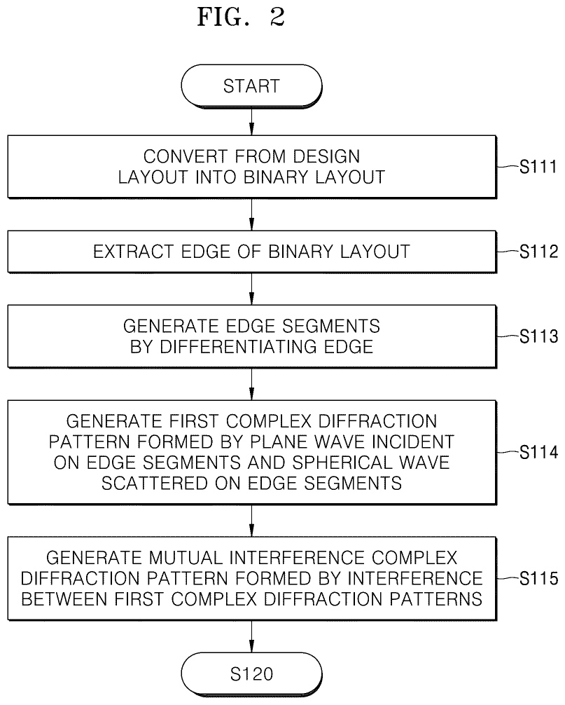

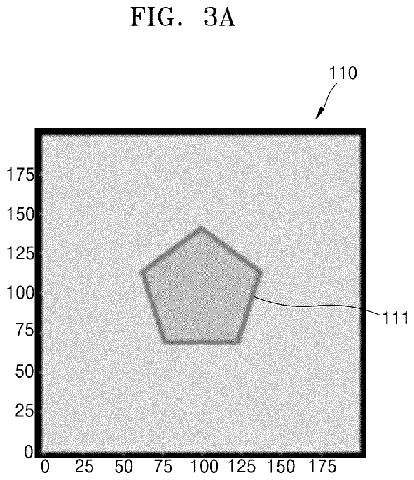

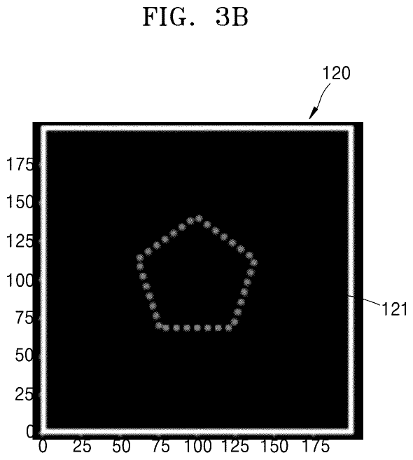

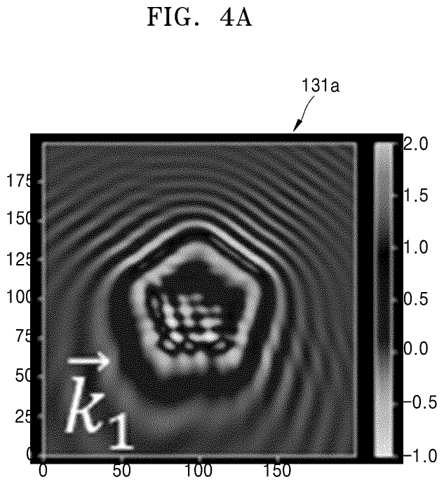

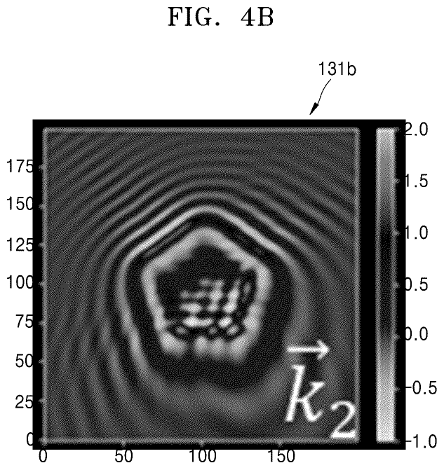

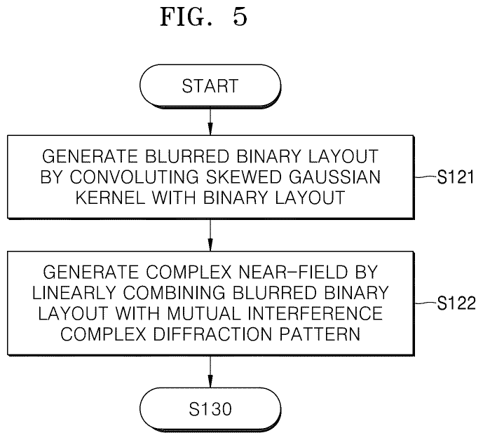

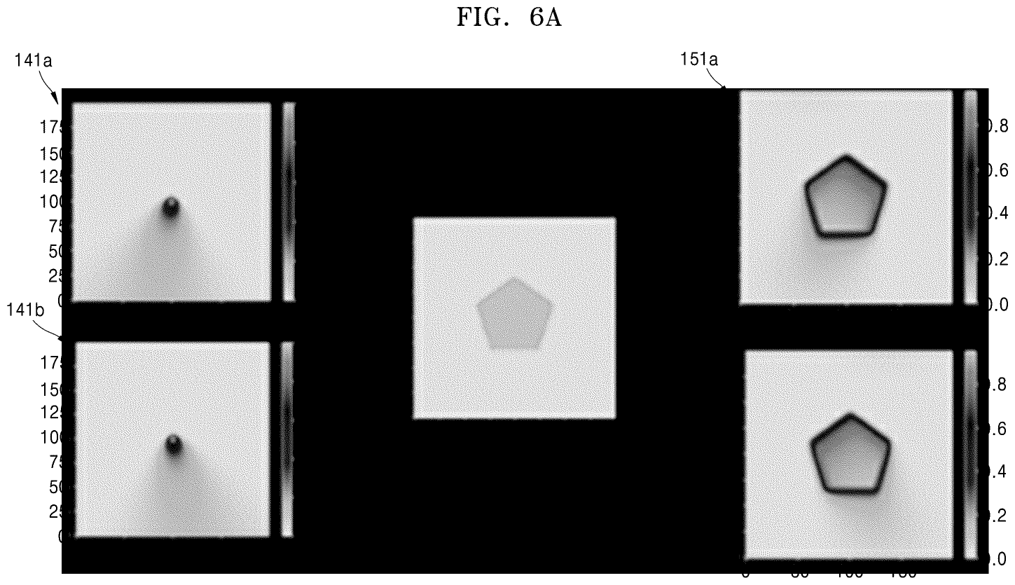

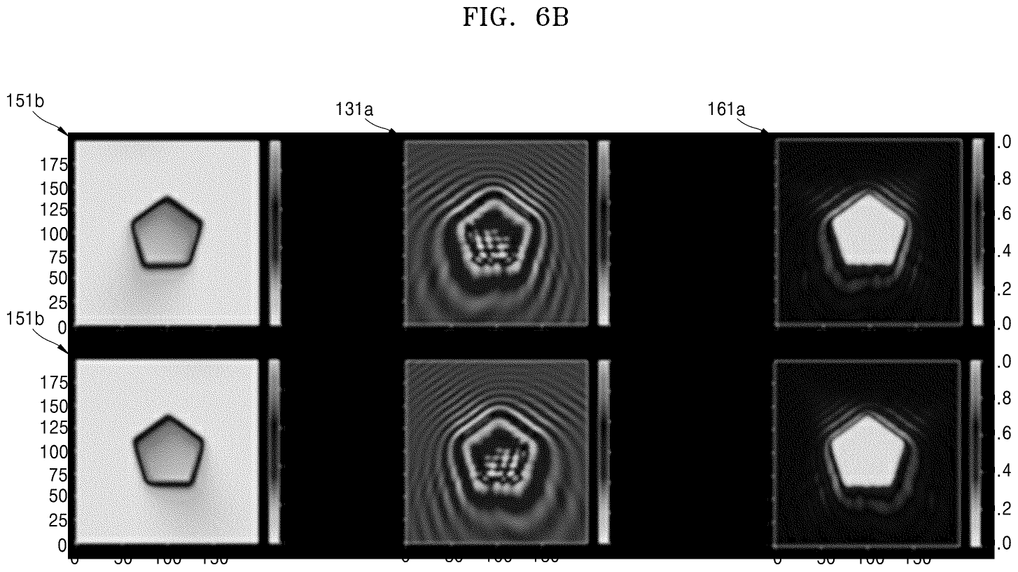

FIG. 1 is a flowchart schematically showing an optimal near-field generation method according to at least one embodiment. FIG. 2 is a flowchart schematically showing an example of a mutual interference complex diffraction pattern generation operation of FIG. 1. FIG. 3A is an image showing a design layout. FIG. 3B is an image showing a binary layout. FIGS. 4A and 4B are images showing a mutual interference complex diffraction pattern. FIG. 5 is a flowchart schematically showing an example of a complex near-field generation operation of FIG. 1. FIG. 6A is an image showing a blurred binary layout generation operation of FIG. 5. FIG. 6B is an image showing a complex near-field generation operation of FIG. 5.

Referring to FIGS. 1 and 2, an optimal near-field generation method according to at least one embodiment may include a mutual interference complex diffraction pattern generation operation S110, a complex near-field generation operation S120, and an optimal near-field generation operation S130.

In the mutual interference complex diffraction pattern generation operation S110, a mutual interference complex diffraction pattern formed by mutual interference between a plurality of spherical waves formed as a certain plane wave (incident on each of a plurality of edge segments differentiated from an edge of a design layout for a target pattern) is scattered on each of the plurality of edge segments may be generated.

A target pattern may refer to a pattern to be formed on a substrate such as a semiconductor (e.g., silicon (Si)) wafer. In other words, a pattern on a mask is used in an exposure process so that a target pattern is formed on the substrate. In general, as a pattern on a mask is projected on a reduced scale and transferred onto a wafer, the pattern on a mask may be larger than the target pattern on the substrate.

A design layout may refer to a layout for a pattern on a mask corresponding to the target pattern. Due to the characteristics of the exposure process, the target pattern on the wafer and an actual pattern on a mask used in the exposure process may have different shapes. More specifically, the pattern on the mask may be based on the target pattern, but may be modified to compensate for image errors (e.g., due to diffraction, interference, process effects, etc.) during the exposure process. However, the shape of the original design layout for the pattern on a mask, in at least some embodiments, may otherwise be substantially the same as and/or similar to the shape of the target pattern on a wafer. In general, the design layout may have a shape of a right-angle design layout. The shape of a right-angle design layout may mean a shape in which the edges consist of straight lines only. However, the shape of a design layout is not limited to the shape of a right-angle design layout. For example, the shape of a design layout may include at least one edge that is not a straight line and/or one or more angles that are not at right-angles.

The design layout may be, as an example, graphic data system (GDS) data. The GDS data may be in a data format used in electronic design automation (EDA). The GDS data may include a polygonal pattern, a text label, and hierarchic information, and the like within the design layout. The design layout, as described in further detail below, may be generated from processing circuitry, such as hardware, software, or a combination thereof configured to output the design layout. For example, the processing circuitry more specifically may include (and/or be included in), but is not limited to, a central processing unit (CPU), a neural processing unit (NPU), deep learning processor (DLP), an arithmetic logic unit (ALU), a digital signal processor, a microcomputer, a field programmable gate array (FPGA), and programmable logic unit, a microprocessor, application-specific integrated circuit (ASIC), etc. In at least some embodiments, the processing circuitry may be connected to and/or included in a mask processing apparatus configured to produce a design layer out based on a received target design and to produce a mask based on the design layout and/or a semiconductor processing apparatus configured to configured to produce a design layer out based on a received target design, produce a mask based on the design layout, and develop the target matter on a surface of a substrate using the produced mask.

For example, the processing circuitry may be included in and/or configured to control a semiconductor processing apparatus such that a production of a mask, and/or a subsequent series of processes (e.g., development, etching, cleaning, or the like) are controlled based on the design layout produced based on the results of a layout design method. As such, a chip may be produced using a mask manufactured based on results of the design layout method.

FIG. 3A shows an example of a design layout 110. Referring to FIG. 3A, the design layout 110 may include a pattern 111 that is pentagonal. The pattern 111 of the design layout 110 is not limited to a pentagonal shape, and may be polygonal, such as triangular, quadrangular, and/or the like, and further have a curved shape.

The mutual interference complex diffraction pattern generation operation S110 may include, as an example, as illustrated in FIG. 2, a converting operation S111 of converting a design layout into a binary layout, an edge extraction operation S112, an edge segment generation operation S113, a first complex diffraction pattern generation operation S114, and a mutual interference complex diffraction pattern generation operation S115.

In the converting operation S111, the design layout 10 of FIG. 3A may be converted into a binary layout 120 of FIG. 3B. In the converting operation S111, edge information of a pattern is extracted from a design layout including pattern information, a text label, and hierarchic information, and the like and converted into the binary layout 120. The binary layout 120 may indicate a pixel value corresponding to an edge of a pattern as 1 and a pixel value of the remaining area as 0.

In the edge extraction operation S112, an edge of the binary layout 120 may be extracted. In the edge extraction operation S112, an edge having a pixel value of 1 may be extracted from the binary layout 120.

In the edge segment generation operation S113, a plurality of edge segments 121 of FIG. 3B may be formed by differentiating the edge extracted from the edge extraction operation S112. The extracted edge may be an outline of the pattern 111. In the edge segment generation operation S113, the outline of the pattern 111 may be differentiated into line segments each having a certain size. The differentiated line segments may be the edge segments 121. Each of the edge segments 121 may operate as a main scatterer that scatters a plane wave incident on the edge segments 121.

In the first complex diffraction pattern generation operation S114, a first complex diffraction pattern by a spherical wave formed as a plane wave is scattered on the edge segments 121 may be generated. In other words, a plane wave may be incident on the edge segments 121 at a certain angle. As the edge segments 121 are main scatterers, the plane wave may be scattered on the edge segments 121. The plane wave may be scattered on the edge segments 121 and may travel as a spherical wave. The spherical wave may generate a first complex diffraction pattern on a virtual two-dimensional plane positioned at a distance equal to the thickness of the mask on which the pattern is formed.

A first complex diffraction pattern Iᵢ(xᵢ, yᵢ) may be generated using the following Equation (1).

$${I}_{i} ( {x}_{i} , {y}_{i} ) = u ( {x}_{i} , {y}_{i} ) \cdot exp ( j ( {k}_{x} \cdot ( x - {x}_{i} ) + {k}_{y} \cdot ( y - {y}_{i} ) ) ) \frac{\text{?}}{\text{?}} exp ( - {α}_{eff} \cdot {r}_{i} ) \qquad Equation ( 1 )$$

$$\text{?} \text{indicates text missing or illegible when filed}$$

In the equation, u(xᵢ, yᵢ) may be a window function, j may be an imaginary number, kₓ may be an x component of an incident direction vector of the plane wave, k_{y} may be a y component of an incident direction vector of the plane wave, k₀ may be an angular wave number, rᵢ may be a distance between the edge segment and the first complex diffraction pattern, thk_{film} may be the thickness of a mask, and α_{eff} may be an effective light absorption coefficient.

The window function u(xᵢ, yᵢ) is a general function used for signal processing and data analysis. The window function u(xᵢ, yᵢ) may correspond to the shape of the pattern 111 within the design layout 110. In other words, the window function u(xᵢ, yᵢ) may be determined depending on the shape of the outermost line of the pattern 111. For example, when the pattern 111 is pentagonal as shown in FIG. 3A, the window function u(xᵢ, yᵢ) may correspond to a pentagon.

In Equation (1), the exponential functions exp(j(kₓ·(x−xᵢ)+k_{y}·(y−yᵢ))) and exp(j(kₓ·(x−xᵢ)+k_{y}·(y−yᵢ))) multiplied to the window function u(xᵢ, yᵢ) include kₓ (which is an x component of an incident direction vector of a plane wave) and k_{y} (which is a y component of an incident direction vector of a plane wave), and may reflect traveling of a plane wave incident at a certain angle toward the edge segments 121. Accordingly, in at least one embodiment, the complex diffraction pattern that changes depending on the direction of incident light may be simulated.

The effective light absorption coefficient α_{eff} may simulate a light absorption phenomenon in a mask formed in a multilayer. In other words, a mask used in an exposure process, such as extreme ultraviolet (EUV) exposure or the like, may include a multilayer. The incident light on the multilayer may be absorbed in each layer of the multilayer. The effective light absorption coefficient α_{eff} may be light absorption occurring in the multilayer of a mask. In at least one embodiment, as Equation (1) for generating a first complex diffraction pattern includes the effective light absorption coefficient α_{eff}, light absorption behavior in a mask including a multilayer may be reflected, and attenuation of scattered light may be included.

In the mutual interference complex diffraction pattern generation operation S115, a mutual interference complex diffraction pattern formed by mutual interference between the first complex diffraction patterns may be generated. The mutual interference complex diffraction pattern may be formed by the mutual interference between the first complex diffraction patterns. The first complex diffraction pattern may be formed by the spherical wave scattered on the edge segments 121, as described above. The first complex diffraction patterns generated by each of the edge segments 121 may interfere with each other. A mutual interference complex diffraction pattern may be formed by the first complex diffraction patterns interfering with each other.

A mutual interference complex diffraction pattern I(x, y) may be generated using the following Equation (2).

$$I ( x , y ) = \text{?} \cdot \text{?} + \text{?} ( x , y ) I ( x , y ) = \text{?} ( {x}_{i} , {y}_{i} ) \cdot \text{?} + \text{?} ( x , y ) \qquad Equation ( 2 )$$

$$\text{?} \text{indicates text missing or illegible when filed}$$

The I_{II}(x, y) may be generated using the following Equation (3).

$$\text{?} ( x , y ) = \text{?} ( c \cdot \text{?} exp ( \text{?} ( \text{?} \cdot ( \text{?} - \text{?} ) + \text{?} \cdot ( \text{?} - \text{?} ) ) ) \frac{\cdot exp ( \text{?} ) \cdot \text{?}}{\text{?}} \text{?} ) \frac{exp ( \text{?} ) \cdot \text{?}}{\text{?}} \cdot exp ( - {α}_{eff} \cdot \text{?} ) \cdot {ds}_{1} \qquad Equation ( 3 )$$

$$\text{?} \text{indicates text missing or illegible when filed}$$

In the equations, x_{I,i} and x_{II,j} may be x coordinates of the edge segments different from each other, y_{I,i} and y_{II,j} may be y coordinates of the edge segments different from each other, rᵢ may be a distance between the first complex diffraction pattern and the edge segment at a coordinate (x_{I,i}, y_{I,i}), and rⱼ may be a distance between the first complex diffraction pattern and the edge segment at a coordinate (x_{II,i}, y_{II,i}).

The mutual interference complex diffraction pattern I(x, y) may be generated, as in Equation (2), by line integrating the first complex diffraction pattern Iᵢ(xᵢ, yᵢ) generated from Equation (1) on all of the edge segments 121.

Equation (2) of generating the mutual interference complex diffraction pattern may be slightly different from a Rayleigh-Sommerfeld diffraction formula for generally obtaining a diffraction pattern. Equation (4) is the Rayleigh-Sommerfeld diffraction formula.

$$I ( x , y ) = \frac{1}{j λ} \text{?} ( x , y \text{?} {x}_{i} , {y}_{i} ) dS = \frac{1}{j λ} \text{?} U ( {x}_{i} , {y}_{i} ) \frac{exp ( \text{?} \cdot {r}_{i} )}{{r}_{i}} cos ( \text{?} ) dS \qquad Equation ( 4 )$$

$$\text{?} \text{indicates text missing or illegible when filed}$$

Equation (4), which is a general Rayleigh-Sommerfeld diffraction formula, obtains a diffraction pattern using surface integration. According to at least one embodiment, as described above, a mutual interference complex diffraction pattern may be obtained using line integration. As the edge segments 121 correspond to a main scatterer that causes wave perturbation, even when a diffraction pattern is obtained using line integration, there may not be much difference from the diffraction pattern obtained using surface integration. In at least one embodiment, faster generations are possible by using line integration, not surface integration, in obtaining a diffraction pattern.

The I_{II}(x, y) means a second-order diffraction contribution. As described above, the plane wave incident on the edge segments 121 is scattered on the edge segments 121 to form a first complex diffraction pattern, and the first complex diffraction patterns formed by being scattered on each of the edge segments 121 interfere with each other so that a mutual interference complex diffraction pattern may be formed. The second-order diffraction may be generated due to the properties of waves. The I_{II}(x, y) may represent a diffraction pattern by the second-order diffraction of scattered light.

FIGS. 4A and 4B are images showing a mutual interference complex diffraction pattern. FIG. 4A shows a first mutual interference complex diffraction pattern 131a formed by a plane wave traveling with a vector k₁, and FIG. 4B shows a second mutual interference complex diffraction pattern 131b formed by a plane wave traveling with a vector k₂. The direction of the vector k₁ may be a direction from 7 o'clock to 1 o'clock, and the direction of the vector k₂ may be a direction from 5 o'clock to 11 o'clock. FIGS. 4A and 4B are images showing the mutual interference complex diffraction pattern obtained from Equation (2) reflecting the incident direction of a plane wave. As illustrated in FIGS. 4A and 4B, according to at least one embodiment, a phenomenon that the diffraction pattern changes as the incident direction of incident light changes is reflected is shown.

In the complex near-field generation operation S120, a complex near-field may be obtained by reflecting, to the mutual interference complex diffraction pattern, a mask three-dimensional (3D) effect that changes depending on the direction in which a plane wave is incident on the edge segments 121. The mask 3D effect means that an undesired pattern is formed because a focus and a pattern arrangement are changed due to a protruding structure of a mask. In detail, an EUV mask may be based on tantalum (Ta) and may have a structure in which an absorbent protrudes on a mask in a 3D shape. EUV light may be incident on a mask based on a central axis with an inclination of a certain angle, for example, 6 degrees. In this state, the light reaching the mask is reflected, and then, a shadowing effect due to the 3D structure of the absorbent or imaging aberration by the mask may occur. Accordingly, it is a problem that the focus and the pattern arrangement are changed so that an undesired pattern is formed. This is referred to as the mask 3D effect.

The mutual interference complex diffraction pattern described above may not reflect the mask 3D effect occurring in the entire pattern, considering that the mutual interference complex diffraction pattern is the resultant from the scattering on the edge segments 121 that is a main scatterer. However, in the complex near-field generation operation S120, a complex near-field may be generated, in which the mask 3D effect is reflected on the mutual interference complex diffraction pattern obtained above.

The complex near-field generation operation S120 may include, as an example, as illustrated in FIG. 5, a blurred binary layout generation operation S121 and a complex near-field generation by linear combination operation S122.

In the blurred binary layout generation operation S121, a blurred binary layout may be generated by convoluting the skewed Gaussian kernel depending on the incident direction of incident light with a binary layout. In at least one embodiment, by using a blurred binary layout generated by convoluting the skewed Gaussian kernel with the binary layout, a shadowing effect according to a k vector that is the incident direction of a plane wave may be reflected on the generation of a complex near-field.

FIG. 6A is an image showing the blurred binary layout generation operation S121 of FIG. 5. Referring to FIG. 6A, a first image 141a represents a skewed Gaussian kernel when light is incident in a direction from 7 o'clock to 1 o'clock, and a second image 141b represents a skewed Gaussian kernel when incident light is incident in a direction from 5 o'clock to 11 o'clock. A first blurred binary layout 151a and a second blurred binary layout 151b may be generated by convoluting a binary layout 110 with each of the first image 141a and the second image 141b. As such, in at least one embodiment, in the complex near-field generation operation S120, by using the skewed Gaussian kernel depending on the incident direction of incident light, a shadowing effect may be reflected by incident light at a certain angle.

Next, in the complex near-field generation by linear combination operation S122, a complex near-field may be generated by linearly combining the blurred binary layout with the mutual interference complex diffraction pattern. The linear combination in the complex near-field generation by linear combination operation S122 is an operation of using a blurred binary layout and a mutual interference complex diffraction pattern as variables, multiplying each of the blurred binary layout and the mutual interference complex diffraction pattern by a constant, and summing the constant-multiplied blurred binary layout and the mutual interference complex diffraction pattern.

FIG. 6B is an image showing the complex near-field generation operation S120 of FIG. 5. Referring to FIG. 6B, the first blurred binary layout 151a and the first mutual interference complex diffraction pattern 131a may correspond to a case in which the incident light travels in a direction from 7 o'clock to 1 o'clock, and the second blurred binary layout 151b and the second mutual interference complex diffraction pattern 131b may correspond to a case in which the incident light travels in a direction from 5 o'clock to 11 o'clock. A first complex near-field 161a may be generated by a linear combination of the first blurred binary layout 151a and the first mutual interference complex diffraction pattern 131a. A second complex near-field 161b may be generated by a linear combination of the second blurred binary layout 151b and the second mutual interference complex diffraction pattern 131b.

In the optimal near-field generation operation S130, an optimal near-field may be generated by optimizing the complex near-field using an artificial neural network (ANN) so as to reduce the difference between a complex near-field and a rigorous near-field of a design layout.

The rigorous near-field may be obtained by solving Maxwell equations at every point (and/or a super majority of the points) in a pattern of a design layout. The complex near-field is generated by line integrating an edge segment of a pattern using the edge segment as a main scatterer, as described above. Accordingly, the complex near-field and the rigorous near-field may have some errors therebetween.

In at least one embodiment, an optimal near-field may be generated by optimizing the complex near-field through an artificial neural network (ANN) learning so as to reduce a difference between the complex near-field and the rigorous near-field generated in the complex near-field generation operation S120.

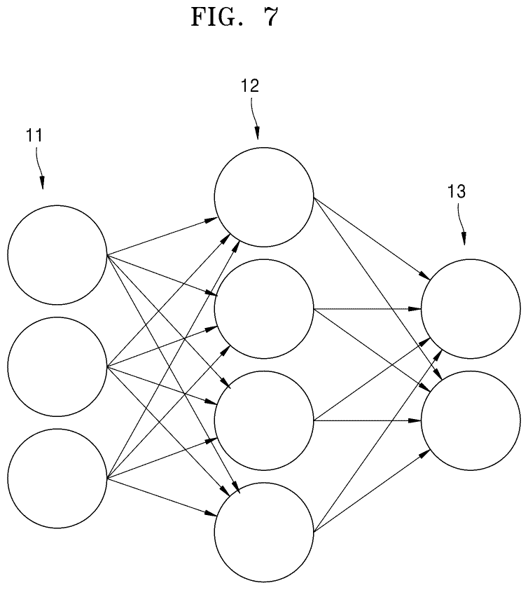

FIG. 7 is a configuration view schematically showing the ANN used for optimal near-field generation. The ANN may include an input layer 11, a hidden layer 12, and an output layer 13. Each layer includes various nodes (“neurons”) that may be stored in various data structures (e.g., data arrangement or executable file).

FIG. 7 illustrates that, for convenience of explanation, the ANN includes one hidden layer 12. However, the disclosure is not limited thereto, and various numbers of hidden layers 12 may be included. Furthermore, in FIG. 7, the input layer 11 is illustrated as including three nodes, and the hidden layer 12 is illustrated as including four nodes. However, the number of nodes included in each of the input layer 11 and the hidden layer 12 is not limited thereto. For example, the input layer 11 may include four or more nodes, and the hidden layer 12 may include several tens of nodes. Furthermore, in FIG. 7, the ANN is illustrated as including a separate input layer 11 for receiving input data, but the input data may be directly input to the hidden layer 12 according to at least one embodiment.

In the ANN, nodes of layers except the output layer 13 may be connected to nodes of the next layer through links for transmitting output signals. Values obtained by multiplying node values of nodes included in the previous layer by a weight assigned to each link may be input to one node through these links. The node values of the previous layer may correspond to axon values, and the weight may correspond to a synaptic weight. The weight may be referred to as a parameter of the ANN. An active function may include a Sigmoid function, a hyperbolic tangent (tanh) function, a rectified linear unit (ReLU) function, and the like.

The ANN may include a multilayer perceptron model (MLP) and/or a convolutional neural network (CNN).

When the ANN is implemented as an MLP, each node of each layer of the ANN may be connected to each node of a continuous layer (referred to as a “full connection”). Each neuron of a hidden layer for the node of the hidden layer may have an activation function.

When the ANN is implemented as a convolutional neural network (CNN) model, the layers of the ANN may include one or more of an input layer, a convolution layer, a fully connected layer, and an output layer. The CNN model may generally include two parts: a feature extractor and a classifier. The convolution layer may extract features by calculating a subset and convolution of a previous layer (including the input layer) by using a small matrix (referred to as a “filter” or “kernel”). The previous layer may extract various features by using various convolution layers. The fully connected layer similar to the MLP may be used as a classifier to classify an input into predetermined classes (including the output layer).

The CNN model may selectively further include, prior to the fully connected layer, a pooling layer and/or one or more rectified linear unit layers interlaced with the convolution layer. The rectified linear unit layer may simulate non-linearity by introducing non-linearity to the CNN model, and the pooling layer may reduce a layer size for saving calculation costs by down-sampling the hidden layer.

For example, when the ANN is a CNN model, a first hidden layer may be a convolution layer, and a second hidden layer may be a fully connected layer. One or more layers of different types may be arranged between the first hidden layer and the second hidden layer.

In the optimal near-field generation operation S130, an optimal near-field in which a difference between the complex near-field and the rigorous near-field is reduced through ANN learning may be generated using the complex near-field and the rigorous near-field as learning (or training) data. For example, the ANN and/or a machine learning processor executing the ANN, may be trained on the complex near-field and rigorous near-field data and trained to produce optimal near-field reliability (e.g., within an error tolerance range), and thereby the ANN and/or a machine learning processor executing the ANN may be configured to generate an optimal near-field of a received design layout based on the training. Additionally, due to the number of adjustable variables, the ANN and/or a machine learning processor executing the ANN may permit the optimal near-field generation operation S130 to be performed within a practical timeframe for even design layouts not included in the training, wherein an optimal near-field generation operation not supported by an ANN may require orders of magnitude increases in time.

During the optimal near-field generation operation S130, the complex near-field may be optimized through a backpropagation process to minimize a value of a loss function indicating a difference between the complex near-field and the rigorous near-field of a design layout, by using a gradient descent algorithm. The effective light absorption coefficient α_{eff} of Equation (1) and the constant c of Equation (3) may be subject to optimization in the ANN learning.

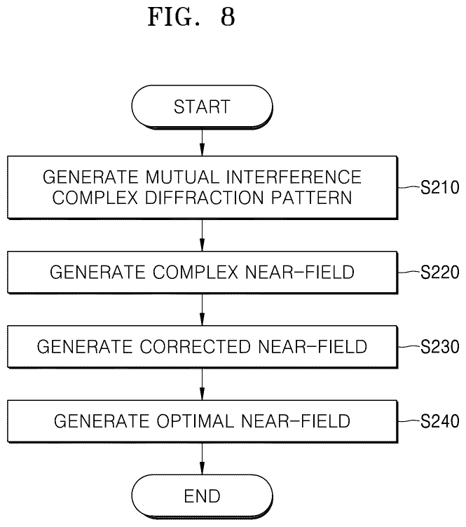

FIG. 8 is a flowchart schematically showing an optimal near-field generation method according to another embodiment.

Referring to FIG. 8, the optimal near-field generation method according to another embodiment may include a mutual interference complex diffraction pattern generation operation S210, a complex near-field generation operation S220, a corrected near-field generation operation S230, and an optimal near-field generation operation S240.

The optimal near-field generation method illustrated in FIG. 8 differs from the optimal near-field generation method illustrated in FIG. 1 in that the corrected near-field generation operation 230 is further provided between the complex near-field generation operation S220 and the optimal near-field generation operation S240. In other words, the mutual interference complex diffraction pattern generation operation S210 and the complex near-field generation operation S220 of the optimal near-field generation method illustrated in FIG. 7 are the same as the mutual interference complex diffraction pattern generation operation S110 and the complex near-field generation operation S120 of the optimal near-field generation method illustrated in FIG. 1. However, while, in the optimal near-field generation method illustrated in FIG. 1, an optimal near-field is generated (S130) by optimizing a complex near-field after generating the complex near-field (S120), in the optimal near-field generation method illustrated in FIG. 8, a corrected near-field is generated (S230) after generating the complex near-field (S220) and an optimal near-field is generated (S240) by optimizing the corrected near-field, which is different from the optimal near-field generation method illustrated in FIG. 1. The differences are described below in detail.

The following descriptions are presented with reference to FIGS. 1 to 7 together, and any previous descriptions given with reference to FIGS. 1 to 7 are briefly given or omitted.

In the mutual interference complex diffraction pattern generation operation S210, a mutual interference complex diffraction pattern formed by mutual interference between a plurality of spherical waves formed as a certain plane wave incident on each of a plurality of edge segments differentiated from an edge of a design layout for a target pattern is scattered on each of the plurality of edge segments may be generated.

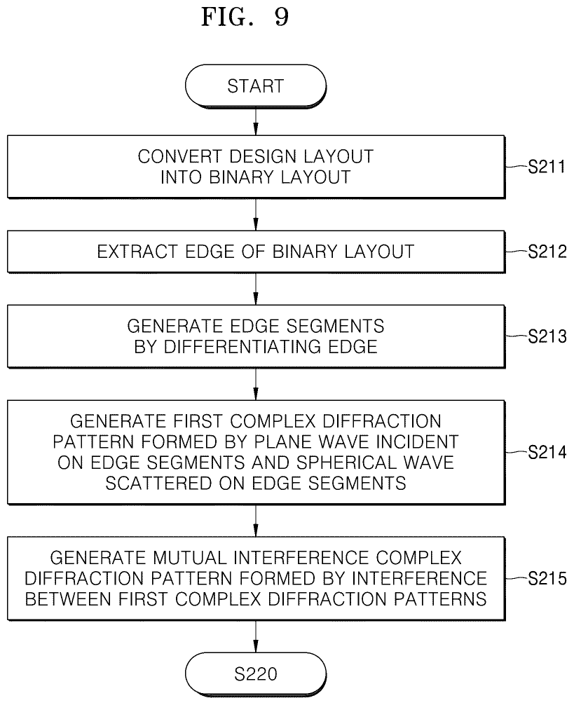

The mutual interference complex diffraction pattern generation operation S210 may include, as an example, as illustrated in FIG. 9, a converting operation S211, an edge extraction operation S212, an edge segment generation operation S213, a first complex diffraction pattern generation operation S214, and a mutual interference complex diffraction pattern generation operation S215. As the operations included in the mutual interference complex diffraction pattern generation operation S210 illustrated in FIG. 9 are the same as and/or substantially similar to the converting operation S111, the edge extraction operation S112, the edge segment generation operation S113, the first complex diffraction pattern generation operation S114, and the mutual interference complex diffraction pattern generation operation S115, which are included in the mutual interference complex diffraction pattern generation operation S110 of FIG. 2, the descriptions about the operations included in the mutual interference complex diffraction pattern generation operation S110 are omitted below.

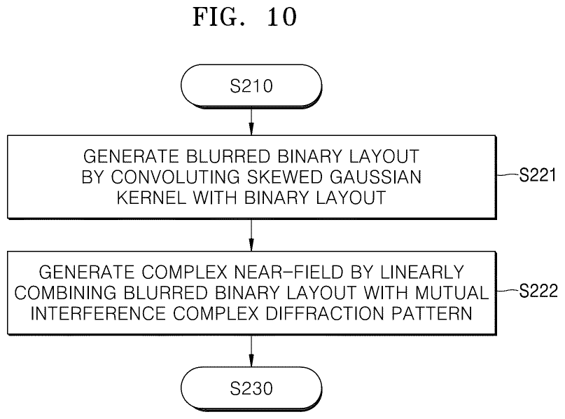

The complex near-field generation operation S220 may include, as an example, as illustrated in FIG. 10, a blurred binary layout generation operation S221 and a linear combination complex near-field generation operation S222. As the operations included in the complex near-field generation operation S220 illustrated in FIG. 10 are the same as and/or substantially similar to the blurred binary layout generation operation S121 and the complex near-field generation by linear combination operation S122 included in the complex near-field generation operation S120 of FIG. 5, the descriptions about the operations included in the complex near-field generation operation S220 are omitted below.

In the corrected near-field generation operation S230, a corrected near-field may be generated by correcting a complex near-field using a Volterra series on an error between the complex near-field and the rigorous near-field of a design layout.

The complex near-field generated in the complex near-field generation operation S220 may have a difference from the rigorous near-field of a design layout. In other words, while the rigorous near-field may be obtained by solving Maxwell equations at every point in a pattern of a design layout, the complex near-field may be generated by line integrating the edge segments of the pattern using the edge segments as a main scatterer, as described above. Accordingly, the complex near-field and the rigorous near-field have an error relative to each other. The reasons for the error may include, for example, an effect according to an optical path change of incident light due to a mask thickness, such as a mask 3D effect, a shadowing effect, or the like, diffracted light components that are scattered on the mask edge along multiple paths and interfere with each other, multiple in/out coupling components arising from interference across multiple layers within a mask, plasmonic absorption that may occur at an interface between a dielectric layer and a metal layer of a mask, or the like.

In at least one embodiment, a corrected near-field may be generated by correcting an error between a complex near-field and a rigorous near-field using a Volterra series.

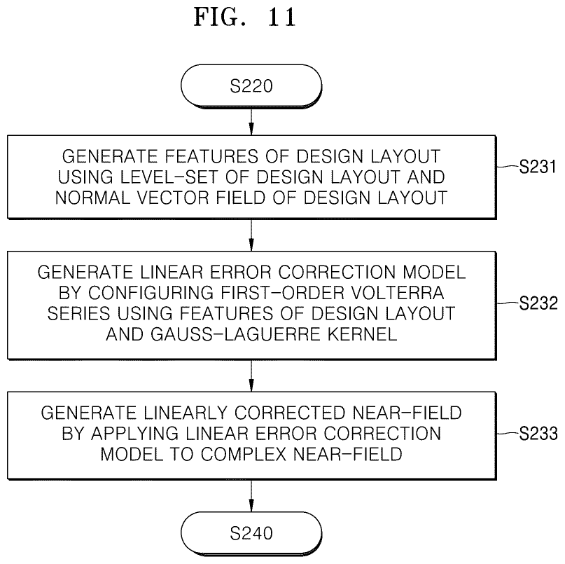

FIG. 11 is a flowchart schematically showing an example of the corrected near-field generation operation S230 of FIG. 8. Referring to FIG. 11, the corrected near-field generation operation S230 may include a design layout features generation operation S231, a linear error correction model generation operation S232, and a linearly corrected near-field generation operation S233.

In the design layout features generation operation S231, a plurality of features of a design layout may be obtained by using a level set of the design layout and a normal vector field of the design layout.

The level set and the normal vector field are generally used in the applied fields of image segmentation, shape restoration, and object tracking. In at least one embodiment, the level set and the normal vector field may be used to obtain features of a design layout.

In detail, the normal vector field refers to a vector field indicating a normal vector of a point at each point of a given surface or curve. The normal vector field is used to identify the reflection of light, the expression and deformation of a surface, and the shape of an object. In other words, the normal vector field may be used to finely analyze the geometric properties of an edge.

The normal vector field of the design layout 10 of FIG. 3A is a set of vectors in a direction perpendicular to the edge of the pattern 111.

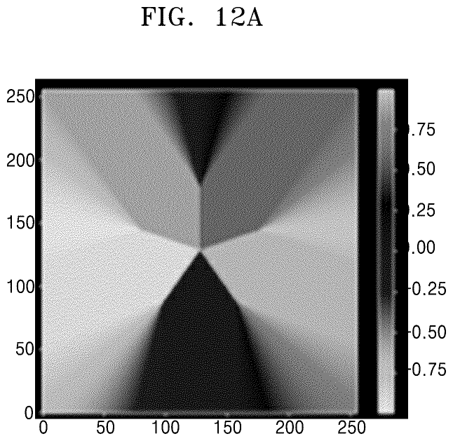

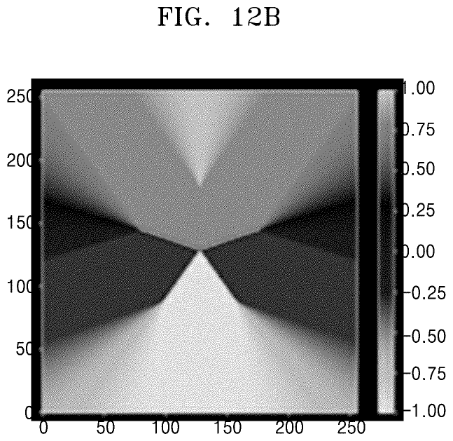

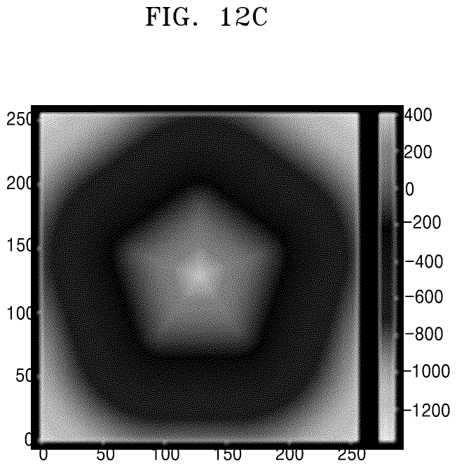

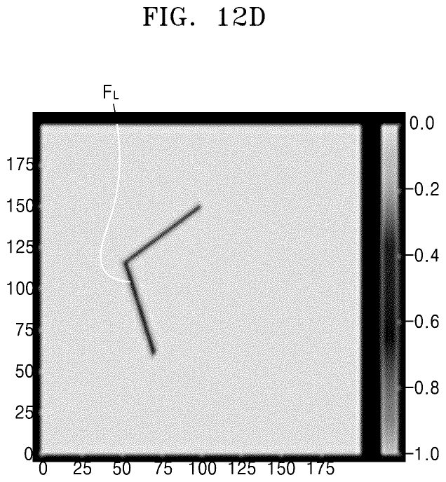

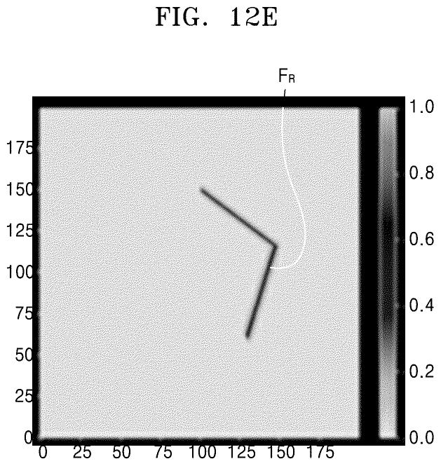

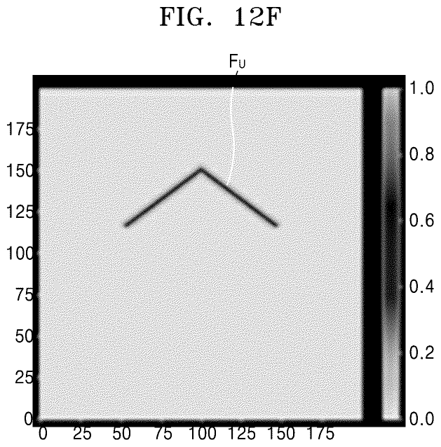

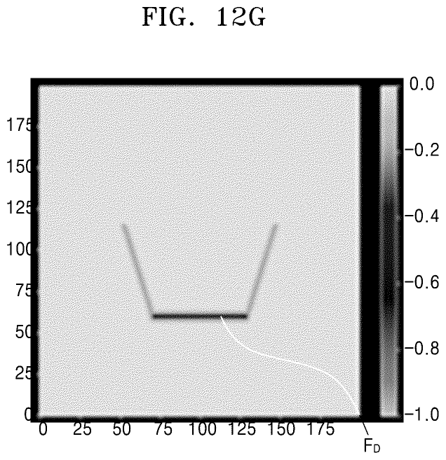

FIG. 12A is an image showing an x component of a normal vector field for an edge of a pattern within a design layout. FIG. 12B is an image showing a y component of a normal vector field for an edge of a pattern within a design layout.

In detail, FIG. 12A is an image showing an x component of a normal vector field for the edge of the pattern 111 of the design layout 110 illustrated in FIG. 3A. FIG. 12B is an image showing a y component of a normal vector field for the edge of the pattern 111 of the design layout 110 illustrated in FIG. 3A.

Referring to FIG. 12A, as the pattern 111 of the design layout 110 illustrated in FIG. 3A is pentagonal, in the image of FIG. 12A showing the x component of a normal vector field at the edge of the pattern 111 that is pentagonal, a value from the center of the image to the right may be positive, and a value from the center of the image to the left may be negative.

Referring to FIG. 12B, as the pattern 111 of the design layout 110 illustrated in FIG. 3A is pentagonal, in the image of FIG. 12B showing the y component of a normal vector field at the edge of the pattern 111 that is pentagonal, a value from the center of the image to the upper side may be positive, and a value from the center of the image to the lower side may be negative.

The level sets are generally used to numerically track and analyze curves and shapes. A level set method is a method indirectly representing a curve (2D) or a surface (3D) in a space of given dimensions. The level sets are used to extract boundaries.

FIG. 12C is an image showing a level set of a pattern within a design layout. In detail, FIG. 12C is an image showing a level set of the pattern 111 of the design layout 110 illustrated in FIG. 3A.

The level cell image of FIG. 12C has a value of 0 at the edge of the pattern (110 of FIG. 3A of the design layout (111 of FIG. 3A), a negative value toward the outside of the edge, and a positive value toward the inside of the edge.

In the design layout features generation operation S231, a plurality of features may be generated at an edge of a pattern within a design layout. In the design layout features generation operation S231, a plurality of features may be extracted from the edge of a pattern of a design layout by using a level set of the design layout and a normal vector field of the design layout.

FIGS. 12D to 12G are images showing features of a pattern within a design layout. FIG. 12D shows a first feature F_{L}, FIG. 12E shows a second feature F_{R}, FIG. 12F shows a third feature F_{U}, and FIG. 12G shows a fourth feature F_{D}. FIGS. 12D to 12G show four features, but the disclosure is not limited thereto, and a plurality of features may be generated in the design layout features generation operation S231.

FIG. 12D shows the first feature L that is a feature for the left edge of the pattern 111 of FIG. 3A. The first feature L may be obtained using the following Equation (5).

$$L = min ( exp ( - c \cdot Lev ) \cdot \text{?} , 0 ) ) L = min ( exp ( - c \cdot Lev ) \cdot \text{?} , 0 ) ) \qquad Equation ( 5 )$$

$$\text{?} \text{indicates text missing or illegible when filed}$$

FIG. 12E shows the second feature FR that is a feature for the right edge of the pattern. The second feature FR may be obtained using the following Equation (6).

$$R = max ( exp ( - c \cdot Lev ) \cdot \text{?} , 0 ) ) R = max ( exp ( - c \cdot Lev ) \cdot \text{?} , 0 ) ) \qquad Equation ( 6 )$$

$$\text{?} \text{indicates text missing or illegible when filed}$$

FIG. 12F shows the third feature Fu that is a feature for the upper edge of the pattern. The third feature Fu may be obtained using the following Equation (7).

$$U = max ( exp ( - c \cdot Lev ) \cdot \text{?} , 0 ) ) U = max ( exp ( - c \cdot Lev ) \cdot \text{?} , 0 ) ) \qquad Equation ( 7 )$$

$$\text{?} \text{indicates text missing or illegible when filed}$$

FIG. 12G shows the fourth feature FD that is a feature for the lower edge of the pattern. The fourth feature FD may be obtained using the following Equation (8).

$$D = min ( exp ( - c \cdot Lev ) \cdot \text{?} , 0 ) ) D = min ( exp ( - c \cdot Lev ) \cdot \text{?} , 0 ) ) \qquad Equation ( 8 )$$

$$\text{?} \text{indicates text missing or illegible when filed}$$

In the equations, “c” is a feature constant, “lev” is a level set, and \vec{X} and \vec{Y} are normal vector fields.

In the linear error correction model generation operation S232, a linear error correction model may be generated by configuring the first-order Volterra series using the plurality of features of the design layout and the Gauss-Laguerre kernel.

A linear error correction model E^{lin}(x, y) may be generated using the following Equation (9).

$${E}^{lin} ( x , y ) = \text{?} {c}_{i} \cdot {v}_{1} ( {K}_{i} ( x , y ) , {F}_{i} ( x , y ) ) \qquad Equation ( 9 )$$

$$\text{?} \text{indicates text missing or illegible when filed}$$

In the equation, “ci” is a fitting constant, “υ₁” is the first-order Volterra series, “Kᵢ(x, y)” is the Gauss-Laguerre kernel, and “Fᵢ(x, y)” is a feature of a design layout.

In the linearly corrected near-field generation operation S233, a linearly corrected near-field may be obtained by applying the linear error correction model to the complex near-field. The linear error correction model may correct a linear error between the complex near-field and the rigorous near-field.

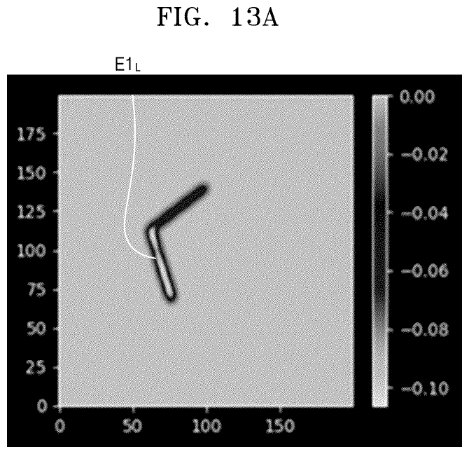

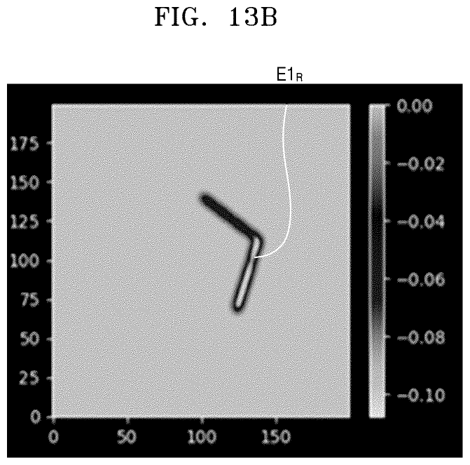

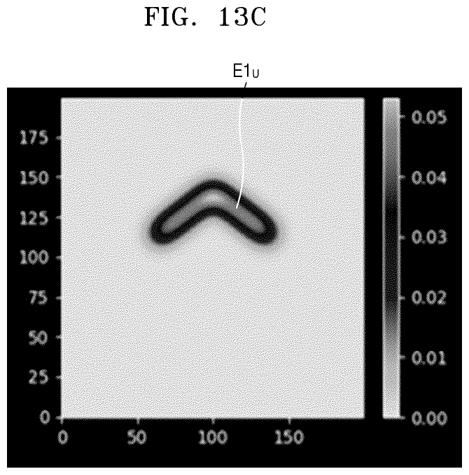

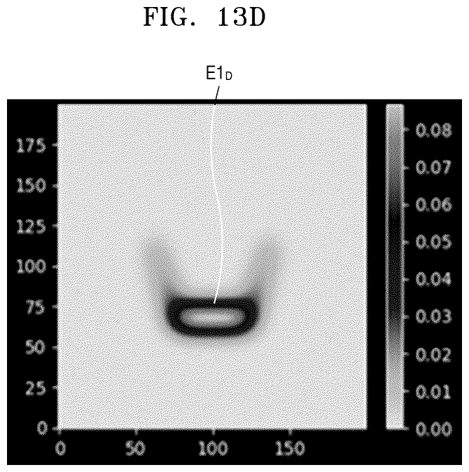

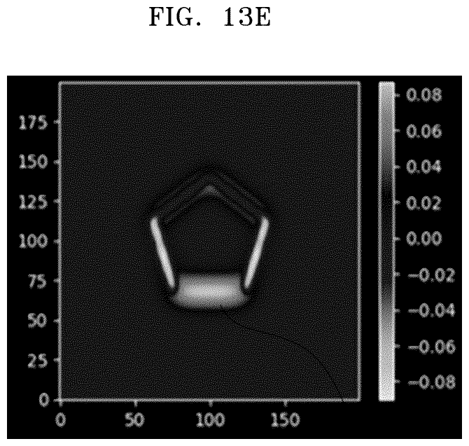

FIGS. 13A to 13D are images showing a linear error corrected feature. FIGS. 13A to 13D show linear error corrected features E1_{L}, E1_{R}, E1_{U}, and E1_{D}, respectively, which are obtained by correcting the features F_{L}, F_{R}, F_{U}, and F_{D} of FIGS. 12D to 12G using the linear error correction model E^{lin}(x, y).

FIG. 13E shows an image E1ₛᵤₘ obtained by summing the linear error corrected features of FIGS. 13A to 13D. In other words, FIG. 13E shows an image obtained by summing the linear error corrected features E1_{L}, E1_{R}, E1_{U}, and E1_{D} respectively illustrated in FIGS. 13A to 13D. FIG. 13E shows a feature image in which a linear error on the edge of a pattern of a design layout is corrected.

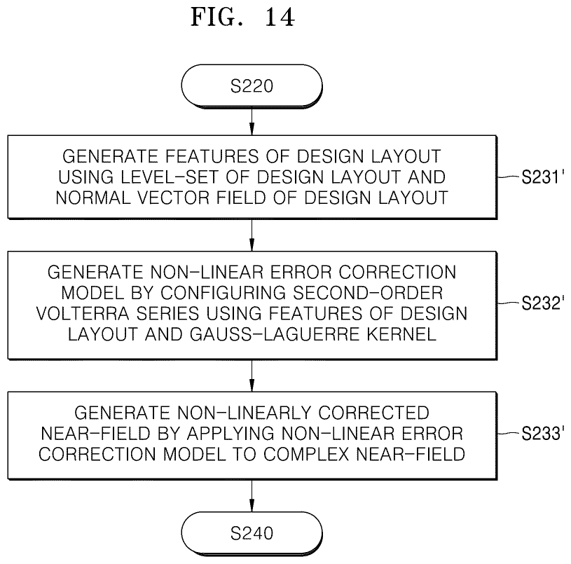

FIG. 14 is a flowchart schematically showing another example of the corrected near-field generation operation S230 of FIG. 8. Referring to FIG. 14, the corrected near-field generation operation may include a design layout features generation operation S231′, a non-linear error correction model generation operation S232′, and a non-linearly corrected near-field generation operation S233′. As the design layout features generation operation S231′ of FIG. 14 is the same as the design layout features generation operation S231 of FIG. 11, a description about the design layout features generation operation S231′is omitted.

After the design layout features generation operation S231′, in the non-linear error correction model generation operation S232′, a non-linear error correction model may be generated by configuring a second-order Volterra series using the plurality of features of the design layout and the Gauss-Laguerre kernel.

A non-linear error correction model E^{non-lin}(x, y) may be generated using the following Equation (10).

$${E}^{nonlin} ( x , y ) = \text{?} {c}_{mn} \cdot {v}_{2} ( {K}_{mn} ( x , y ) , {K}_{mn} ( x , y ) , {F}_{m} ( x , y ) , {F}_{n} ( x , y ) ) \qquad Equation ( 10 )$$

$$\text{?} \text{indicates text missing or illegible when filed}$$

In the equation, cₘₙ may be a fitting constant, and υ₂ may be the second-order Volterra series, Kₘₙ(x, y) may be a Gauss-Laguerre kernel, and Fₘ(x, y) and Fₙ(x, y) may be features of a design layout.

The non-linear error correction model E^{non-lin}(x, y) may include a non-linear error correction model including a self-coupling component and a non-linear error correction model including a mutual-coupling component, according to a Gauss-Laguerre kernel.

In detail, a Gauss-Laguerre kernel K^{mn}(x, y) may include a self-coupling component and a mutual-coupling component. The self-coupling component is a case when m and n are the same, and the mutual-coupling component is a case when m and n are different from each other. For example, m and n may each be any one of the first feature L, the second feature R, the third feature U, and the fourth feature D. When both of m and n are the first feature L, the Gauss-Laguerre kernel may include a self-coupling component. When both of m and n are the second feature R, both of m and n are the third feature U, or both of m and n are the fourth feature D, the Gauss-Laguerre kernel may also include a self-coupling component. In Equation (10), when m and n are the same, the non-linear error correction model may be a non-linear error correction model including a self-coupling component.

The mutual-coupling component corresponds to a case when m and n are different from each other. For example, when m is the first feature L, and n is any one of the second feature R, the third feature U, and the fourth feature D, the Gauss-Laguerre kernel may include a mutual-coupling component. In Equation (10), when m and n are different from each other, the non-linear error correction model may be a non-linear error correction model including a mutual-coupling component.

In the non-linearly corrected near-field generation operation S233′, a non-linearly corrected near-field may be obtained by applying the non-linear error correction model to the complex near-field. The non-linear error correction model may correct a non-linear error between the complex near-field and the rigorous near-field.

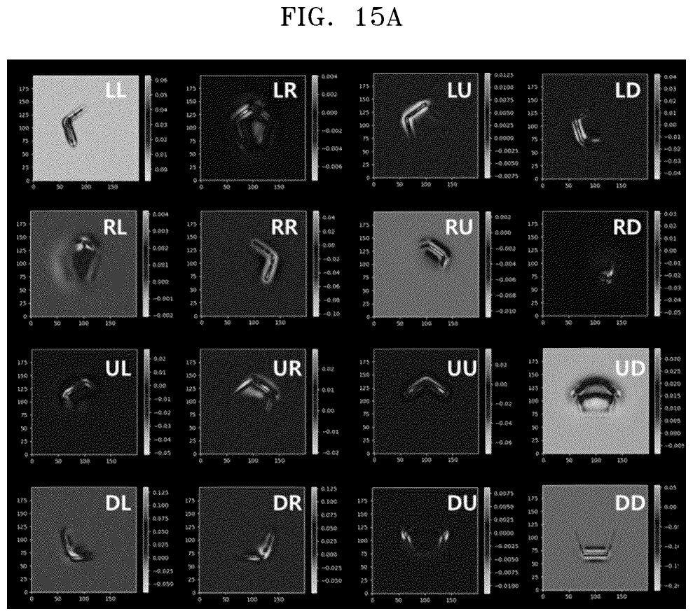

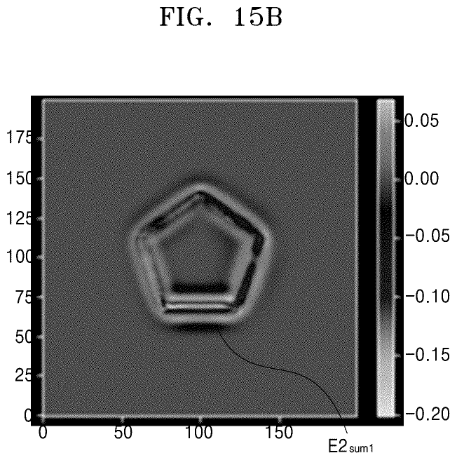

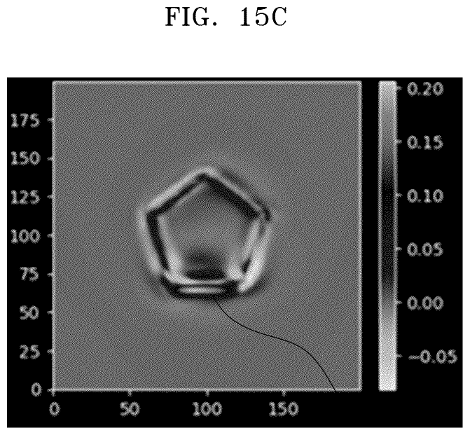

FIG. 15A includes images showing non-linear error corrected features. Referring to FIG. 15A, LL, RR, UU, and DD are feature images corrected according to a non-linear error correction model including a self-coupling component. LR, LU, LD, RL, RU, RD, UL, UR, UD, DL, DR, and DU are feature images corrected according to a non-linear error correction model including a mutual-coupling component.

FIG. 15B is an image E2ₛᵤₘ₁ obtained by summing self-coupled non-linear error corrected features. In other words, the image E2ₛᵤₘ₁ is an image obtained by summing the LL, RR, UU, and DD images of FIG. 15A.

FIG. 15C is an image E2ₛᵤₘ₂ obtained by summing mutually coupled non-linear error corrected features. In other words, the image E2ₛᵤₘ₂ is an image obtained by summing the LR, LU, LD, RL, RU, RD, UL, UR, UD, DL, DR, and DU images of FIG. 15B.

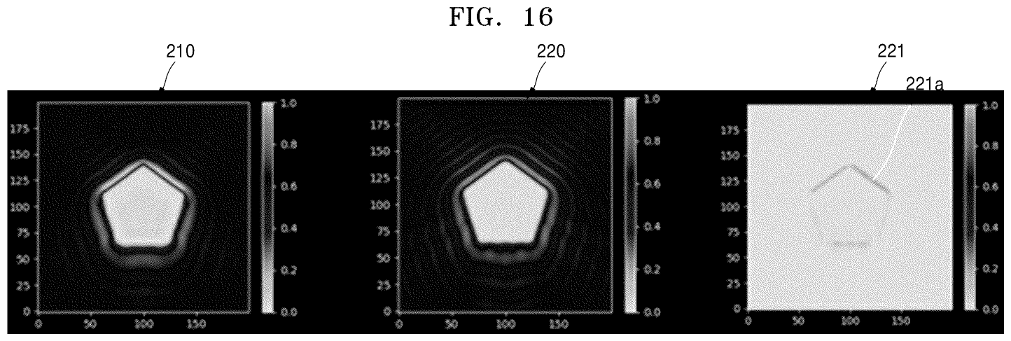

FIG. 16 is an image showing a rigorous near-field, a complex near-field, and a difference between the rigorous near-field and the complex near-field. Referring to FIG. 16, a first image 221 shows an error 221a between a rigorous near-field 210 and a complex near-field 220. It may be checked from the first image 221 that the error 221a exists in the edge of a pattern of.

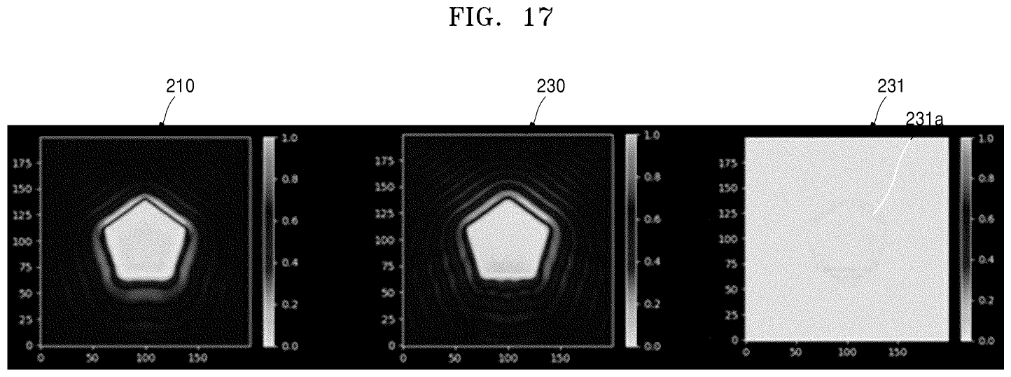

FIG. 17 is an image showing a rigorous near-field, a linearly corrected near-field, and a difference between the rigorous near-field and the linearly corrected near-field. Referring to FIG. 17, a second image 231 shows an error 231a between the rigorous near-field 210 and a linearly corrected near-field 230. Although it may be checked in the second image 23 that the error 231a exists in the edge of a pattern, it may be seen that the error 231a is reduced compared with the first image 221.

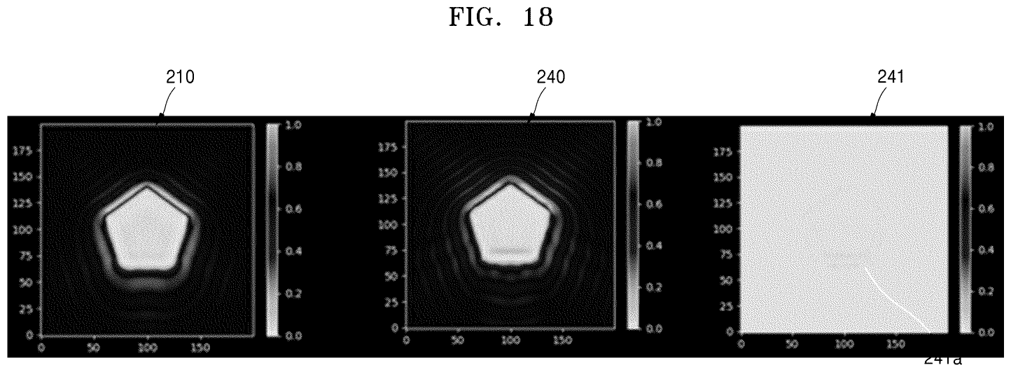

FIG. 18 is an image showing a rigorous near-field, a self-coupled non-linearly corrected near-field, and a difference between the rigorous near-field and the self-coupled non-linearly corrected near-field. Referring to FIG. 18, a third image 241 shows an error 241a between the rigorous near-field 210 and a self-coupling non-linearly corrected near-field 240. Although it may be checked in the third image 241 that the error 241a exists in the edge of a pattern, it may be seen that the error 241a is reduced compared with the first image 221 and the second image 231.

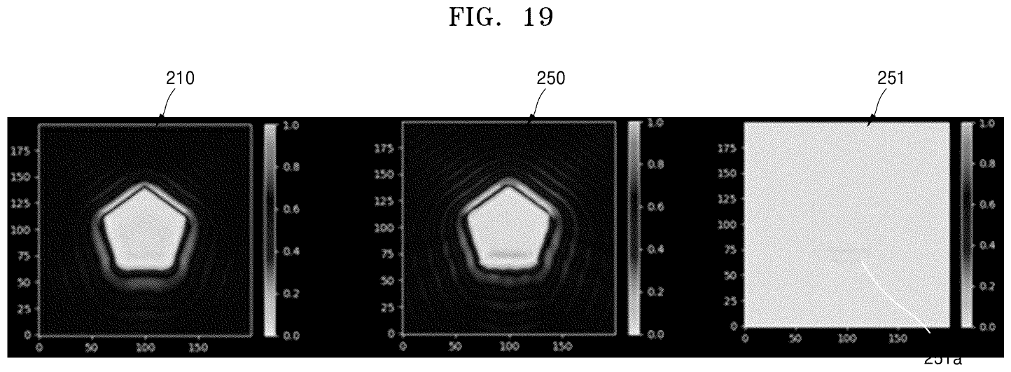

FIG. 19 is an image showing a rigorous near-field, a mutually coupled non-linearly corrected near-field, and a difference between the rigorous near-field and the mutually coupled non-linearly corrected near-field. Referring to FIG. 19, a fourth image 251 shows an error 251a between the rigorous near-field 210 and a mutual coupling non-linearly corrected near-field 250. Although it may be checked in the fourth image 251 that the error 251a exists in the edge of a pattern, it may be seen that the error 251a is reduced compared with the first image 221 and the second image 231.

In the optimal near-field generation operation S240, an optimal near-field may be generated by optimizing the corrected near-field using an ANN so as to reduce a difference between the corrected near-field and the rigorous near-field of a design layout. The corrected near-field and the rigorous near-field may be used as learning data of ANN learning.

In the optimal near-field generation operation S240, the complex near-field may be optimized to minimize a value of a loss function indicating a difference between the complex near-field and the rigorous near-field of a design layout, by using a gradient descent algorithm. The effective light absorption coefficient α_{eff} of Equation (1), the constant c of Equation (3), the constant cᵢ of Equation (9), the constant cₘₙ of Equation (10) may be subject to the optimization in the ANN learning.

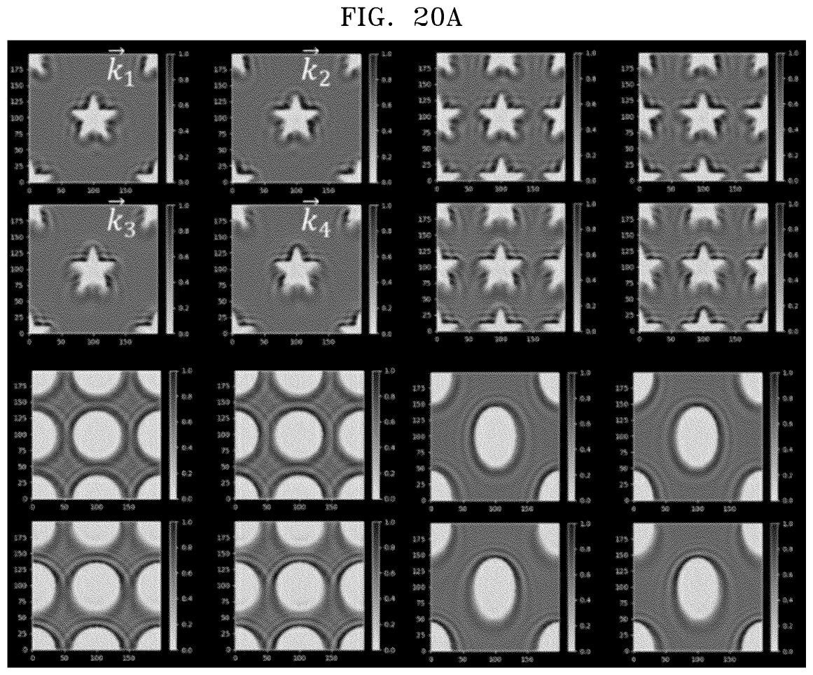

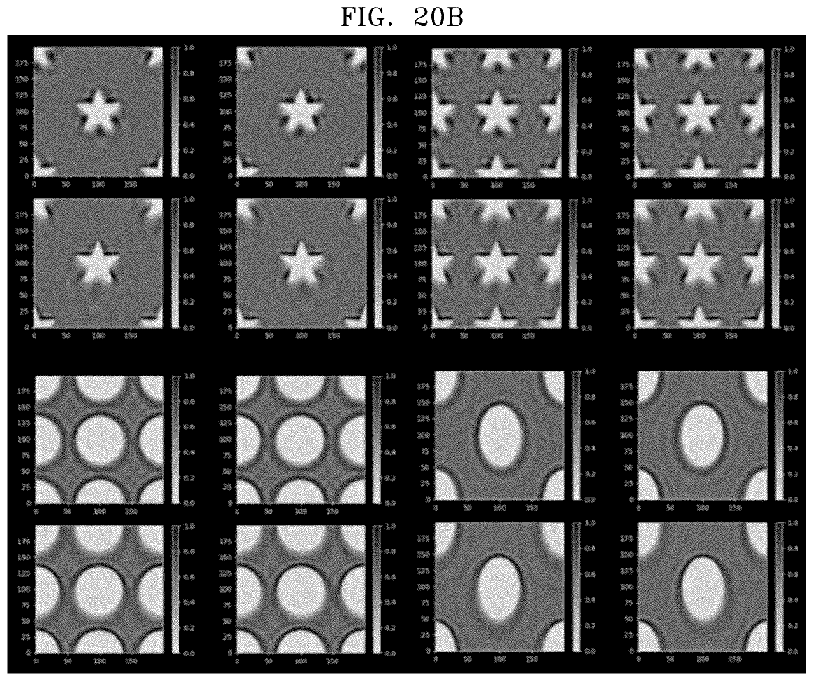

FIG. 20A includes images showing optimal near-fields for patterns of various shapes formed according to the optimal near-field generation method according to at least one embodiment. FIG. 20B includes images showing rigorous near-fields for patterns of various shapes.

The images of FIG. 20A are optimal near-field images generated according to the optimal near-field generation method for star, circle, and overall patterns after optimizing the optimal near-field generation method by training a design layout having a quadrangular pattern. In contrast, the images of FIG. 20B are rigorous near-field images obtained using the Maxwell equations on a design layout having start, circular, and oval patterns. When FIG. 20A and FIG. 20B are compared with each other, it may be seen that the error therebetween is not much (e.g., within a tolerance range).

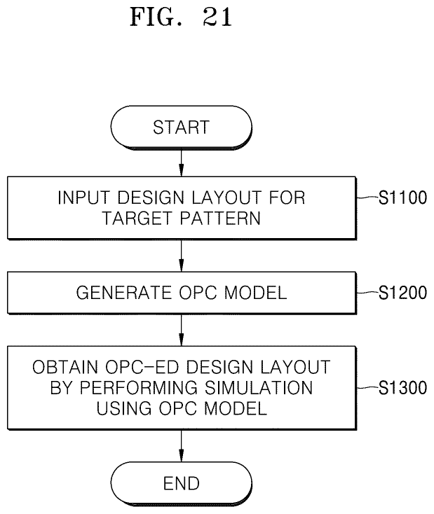

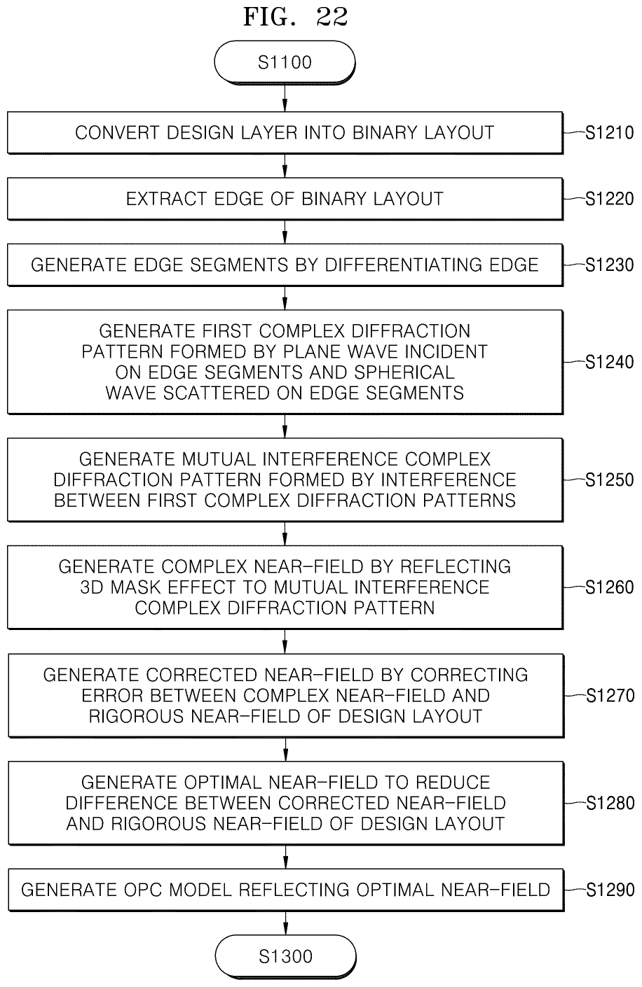

FIG. 21 is a flowchart schematically showing an optical proximity correction (OPC) method according to at least one embodiment. FIG. 22 is a flowchart schematically showing an OPC model generation operation of FIG. 21. The following descriptions are presented with reference to FIGS. 1 to 20B, and any previous descriptions given with reference to FIGS. 1 to 20B are briefly given or omitted.

In the OPC method according to at least one embodiment, an input of a design layout for a target pattern may be received (S1100). The target pattern may refer to a pattern to be formed on a silicon (Si) substrate such as a wafer. In other words, a pattern on a mask is transferred to a substrate through an exposure process so that a target pattern may be formed on the substrate. In general, as a pattern on a mask is projected on a reduced scale and transferred onto a wafer, the pattern on a mask may be larger than the target pattern on the substrate.

A design layout may refer to a layout for a pattern on a mask corresponding to the target pattern. Due to the characteristics of the exposure process, the target pattern on the wafer and an actual pattern on a mask used in the exposure process may have different shapes. However, the shape of the original design layout for the pattern on a mask may be substantially the same as the shape of the target pattern on a wafer. In general, the design layout may have a shape of a right-angle design layout. The shape of a right-angle design layout may mean a shape in which the edges consist of straight lines only. However, the shape of a design layout is not limited to the shape of a right-angle design layout.

Then, for a design layout, an OPC model that reflects the properties of photoresist (PR) and an optical phenomenon in an exposure process may be generated (S1200).

An OPC model generation operation may include optimization of a defocus stand (DS) location, a best focus (BF) location, or the like in the exposure process, in reflecting the optical phenomenon in an exposure process. Also, the OPC model generation operation may further include generation of a mask image or the like considering a light diffraction phenomenon or an optical state of exposure equipment. However, the generation of an OPC model is not limited to the above descriptions. In other words, the generation of an OPC model may include various contents related to the optical phenomenon in an exposure process. For example, in relation with the OPC model generation, the calculation of an optical mask image, that is, a near-field image of a mask, considering a mask topography effect, may be preceded. A rigorous simulation method, such as rigorous coupled-wave analysis (RCWA) and/or finite difference time domain (FDTD) simulation, may be used for the calculation of a near-field image of a mask, but the examples are not limited thereto; for example, an edge filter may be often used for a fast calculation of the near-field image of a mask.

In the reflection of the properties of PR, the OPC model generation operation may include the optimization of a threshold value of PR. The threshold value of PR is a threshold value at which a chemical change occurs in the exposure process. For example, the threshold value may be given as the intensity of exposure light. Furthermore, the generation of an OPC model may include selecting appropriate kernel functions from various resist kernel functions and combining the selected kernel functions. The kernel function, which is a base function used for non-parametric estimation technology, may be used to simulate the properties of a resist image in the OPC model. The OPC method according to at least one embodiment may apply, in a process of generating a second OPC model, a target pattern or a combination of different kernel functions for each area within a design layout corresponding thereto.

According to the OPC model generation operation S1200 according to at least one embodiment, as illustrated in FIG. 22, a converting operation S1210 to an OPC model generation operation S1290 by reflecting an optimal near-field may be sequentially performed. The converting operation S1210 to an optimal near-field generation operation S1280 are the same as and/or substantially similar to the converting operation S111 to the optimal near-field generation operation S130 in FIGS. 1, 2, and 5 and/or the converting operation S211 to the optimal near-field generation operation S240 in FIGS. 8 to 11.

After an optimal near-field is generated, an OPC model reflecting the optimal near-field may be generated (S1290). The OPC model may correspond to part of an OPC model used as simulation in the OPC method.

For reference, the OPC method is a method that suppresses the occurrence of the optical proximity effect (OPE) by correcting the design layout of a pattern on a mask to overcome the occurrence of the OPE during the exposure process due to the influence of neighboring patterns as a pattern on a mask becomes finer. In other words, due to OPE, the size and the shape of a pattern formed on a wafer change depending on the density/arrangement of the pattern on a mask, and the OPC method may be performed to compensate for the change. Although various methods may be used during performing the OPC method, correction using the OPC model may be mainly performed.

The OPC method is largely divided into two; one is a rule-based OPC method, and the other is a simulation-based or model-based OPC method. The model-based OPC method may be advantageous in terms of time and cost because the method uses only the measurement results of representative patterns without having to measure all of a large number of test patterns. The OPC method according to at least one embodiment may be, for example, a model-based OPC method, that is, a correction method using an OPC model. The OPC model, which is a simulation model that outputs the form of the exposure result on a wafer for the design layout of a specific pattern on a mask, may output a simulation image by reflecting the mask, an optical phenomenon, and resist properties.

The OPC method may include a method of adding sub-lithographic features called serifs or a method of adding sub-resolution assist features (SRAFs), such as scattering bars, to the corners of a pattern, as well as a method of modifying the layout of a pattern. The serifs, which are generally quadrangular features located on each corner of pattern, may be used to “sharpen” the corners of a pattern or to compensate for distortion factors caused by intersections of patterns. The SRAFs, which are auxiliary features introduced to solve the OPC deviation problem caused by the density difference in the pattern, are features formed with a size smaller than the resolution of exposure equipment and thus not transferred to the resist layer.

The OPC method first prepares basic data for OPC. The basic data may include data on the shape of the patterns of a sample, the location of the patterns, the type of measurement such as a measurement of a space or line of the pattern, and the basic measurement value. Furthermore, the basic data may include information on the thickness, refractive index, and dielectric constant of PR and may include a source map for the type of an illumination system. The basic data is not limited to the data described above.

After the OPC model generation, a simulation using an OPC model is performed so that an OPC-ed design layout is obtained (S1300).

By performing the simulation using an OPC model, a simulation image corresponding to a target pattern that is an OPC resultant may be generated. A contour may be extracted from the simulation image. When the contour is similar to the target pattern as much as possible, a design layout corresponding thereto may be obtained as an OPC-ed design layout. As a result, the OPC method may be considered as a process of making the contour extracted through the simulation using the OPC model as similar as possible to the shape of the target pattern. The simulation process and comparison process by the OPC model may be repeated tens to hundreds of times, without being completed in one time.

In detail, when a design layout is first input, the design layout may be divided into a plurality of segments and input to an OPC model. For reference, the segment may be referred to as a fragment, and also may refer to a line in the form of a straight line corresponding to an edge of a design layout or to data about the line. Then, a simulation image is generated through a simulation using an OPC model, and a contour corresponding to the target pattern is extracted from the simulation image. Next, an edge placement error (EPE) is calculated by comparing the target pattern and the contour. The EPE refers to a difference between the edge of the target pattern and the simulation contour, and the EPE is usually calculated at each set evaluation point. Then, the positions of the segments are changed and the contour is extracted again through a simulation using an OPC model and the EPE is calculated. The process may be repeated until the EPE is within a set range or the number of repetitions reaches a set number. After the repetition is completed, a final design layout may correspond to the OPC-ed design layout.

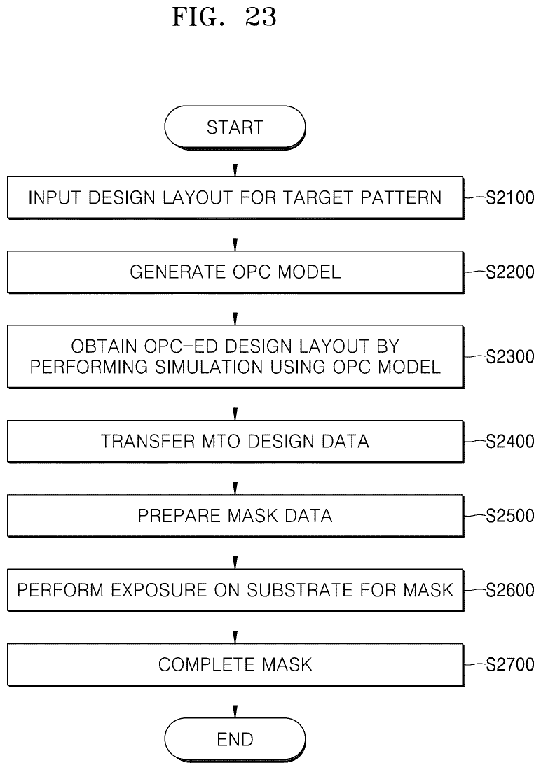

FIG. 23 is a flowchart schematically showing a process of a mask manufacturing method including the OPC method according to at least one embodiment. The following descriptions are presented with reference to FIGS. 1, 2, and 5 (or FIGS. 8 to 11) together, and any previously described portions are briefly given or omitted.

In a mask manufacturing method (hereinafter, briefly referred to as the ‘mask manufacturing method’) including the OPC method according to at least one embodiment, an operation S2100 of receiving an input of a design layout for a target pattern to an operation S2300 of obtaining an OPC-ed design layout are sequentially performed. The operation S2100 of receiving an input of a design layout for a target pattern to the operation S2300 of obtaining an OPC-ed design layout are the same as the operation S1100 of receiving an input of a design layout for a target pattern to the operation S1300 of obtaining an OPC-ed design layout of the OPC method in FIGS. 21 and 22.

Then, mask tape-out (MTO) design data may be transferred to a mask manufacturing server (S2400). Generally, MTO may mean requesting mask manufacturing by transferring data on the final design layout obtained through the OPC method to a mask production team. Accordingly, in the mask manufacturing method according to at least one embodiment, the MTO design data may mean, as a result, the OPC-ed design layout obtained through the OPC method or data thereon. Such MTO design data may have a graphics data format used in EDA software. For example, the MTO design data may have a data format, such as graphic data system II (GDS2) or open artwork system interchange standard (OASIS).

Then, mask data preparation (MDP) is performed (S2500). The mask data preparation may include: i) a format conversion referred to as, for example, fracturing; ii) augmentation of a barcode for machine reading, a standard mask pattern for inspection, or a job deck; and iii) verification of automatic and manual methods. The job deck may mean making a text file about a series of commands, such as multiple mask files arrangement information, a reference dose, or an exposure speed or method.

The format conversion, that is, fracturing, may mean a process of fracturing the MTO design data for each area into a format for electron (E) beam exposure. The fracturing may include data manipulation, for example, size scaling, data sizing, data rotation, pattern reflection, or color inversion. In the conversion process through fracturing, data may be corrected for numerous systematic errors that may occur anywhere in the transfer process from design data to an image on the wafer.

A data correction process on the systematic errors may be referred to as mask process correction (MPC), and may include, for example, a task of increasing linewidth scaling and pattern arrangement precision, which are referred to as CD scaling. Accordingly, the fracturing may contribute to quality improvement of a final mask, and furthermore, the fracturing may be a process performed in advance for the mask process correction. The systematic errors may be caused by distortion occurring in an exposure process, a mask development and etching process, and a wafer imaging process.

The mask data preparation may include the MPC. The MPC refers to a process of correcting an error occurring during the exposure process, that is, a systematic error, as described above. The exposure process may be a concept that generally includes E-beam writing, development, etching, or baking. In addition, data processing may be performed before the exposure process. The data processing, which is a preprocessing process of a kind of mask data, may include grammar check or exposure time anticipation on the mask data.

After the mask data preparation, a substrate for a mask may be exposed based on the mask data (S2600). The exposure may refer to, for example, E-beam writing. The E-beam writing may be performed by a method, for example, gray writing using a multi-beam mask writer (MBMW). Furthermore, the E-beam writing may be performed using a variable shape beam (VSB) writer.

After the mask data preparation and before the exposure process, a process of converting the mask data into pixel data may be performed. The pixel data is data directly used for actual exposure and may include data about the shape to be exposed and data about a dose assigned to each shape. The data about the shape may include bit-map data obtained through rasterization of shape data, that is, vector data.

After the exposure process, a series of processes are performed so that a mask is completed (S2700). The series of processes may include, for example, processes of development, etching, or cleaning. Furthermore, the series of processes for mask manufacturing may include a measurement process, a defect inspection process, or a defect repair process. Furthermore, the series of processes for mask manufacturing may include a pellicle application process. The pellicle application process may mean a process of attaching a pellicle to the mask surface to protect the mask from subsequent contamination during delivery and the mask's usable lifespan, once it is confirmed through final cleaning and inspection that there are no contaminating particles or chemical stains.

While the inventive concept have been particularly shown and described with reference to embodiments thereof, it will be understood that various changes in form and details may be made therein without departing from the spirit and scope of the following claims.

What is claimed is:

1. An optimal near-field generation method comprising:
obtaining a mutual interference complex diffraction pattern of a design layout for a target pattern, the mutual interference complex diffraction pattern representing a pattern formed by mutual interference between a plurality of spherical waves formed as a plane wave incident at an angle with respect to each of a plurality of edge segments of the design layout is scattered on each of the plurality of edge segments;
obtaining a complex near-field by reflecting, to the mutual interference complex diffraction pattern, a mask three-dimensional (3D) effect that changes depending on a direction in which the plane wave is incident to the plurality of edge segments; and
obtaining an optimal near-field by reducing a difference between the complex near-field and a rigorous near-field of the design layout using an artificial neural network.

2. The optimal near-field generation method of claim 1, wherein the obtaining of the mutual interference complex diffraction pattern comprises:
converting the design layout into a binary layout;
extracting an edge of the binary layout;
generating a plurality of edge segments by differentiating the edge;
obtaining a first complex diffraction pattern formed by the plurality of spherical waves as the plane wave at a certain angle, with respect to the plurality of edge segments, is scattered on the plurality of edge segments; and
obtaining the mutual interference complex diffraction pattern formed by mutual interference between the first complex diffraction patterns.

3. The optimal near-field generation method of claim 2, wherein the first complex diffraction pattern Iᵢ(xᵢ, yᵢ) is generated using Equation (1),
$${I}_{i} ( {x}_{i} , {y}_{i} ) = u ( {x}_{i} , {y}_{i} ) \cdot exp ( j ( {k}_{x} \cdot ( x - {x}_{i} ) + {k}_{y} \cdot ( y - {y}_{i} ) ) ) \frac{\text{?}}{\text{?}} exp ( - {α}_{eff} \cdot \text{?} ) , \qquad Equation ( 1 )$$
$$\text{?} \text{indicates text missing or illegible when filed}$$
wherein u(xᵢ, yᵢ) represents a window function,
j represents an imaginary singular number,
kₓ represents an x component of an incident direction vector of the plane wave,
k_{y} represents a y component of an incident direction vector of the plane wave,
k₀ represents an angular wave number,
rᵢ represents a distance between the edge segment and the first complex diffraction pattern,
thk_{film} represents a thickness of a mask, and
α_{eff} represents an effective light absorption coefficient.

4. The optimal near-field generation method of claim 3, wherein the mutual interference complex diffraction pattern I(x, y) is generated using Equation (2),
$$I ( x , y ) = \text{?} {I}_{i} ( {x}_{i} , {y}_{i} ) \cdot {ds}_{1} + \text{?} ( x , y ) I ( x , y ) = \text{?} {I}_{i} ( {x}_{i} , {y}_{i} ) \cdot {ds}_{1} + \text{?} ( x , y ) , \qquad Equation ( 2 )$$
$$\text{?} \text{indicates text missing or illegible when filed}$$
wherein I_{II}(x, y) is a second-order diffraction contribution that is generated using Equation (3),
$$\text{?} ( x , y ) = \text{?} ( C \cdot \text{?} exp ( \text{?} ( \text{?} \cdot ( \text{?} - \text{?} ) + \text{?} \cdot ( \text{?} - \text{?} ) ) ) \frac{\text{?}}{\text{?}} \cdot \text{?} ) \frac{\text{?}}{\text{?}} \cdot exp ( - {α}_{eff} \cdot \text{?} ) \cdot \text{?} , \qquad Equation ( 3 )$$
$$\text{?} \text{indicates text missing or illegible when filed}$$
wherein x_{I,i} and x_{II,j} represent x coordinates of the edge segments different from each other,
y_{I,i} and y_{II,j} represent y coordinates of the edge segments different from each other,
rᵢ represents a distance between the first complex diffraction pattern and the edge segment at a coordinate (x_{I,i}, y_{I,i}), and
rⱼ represents a distance between the first complex diffraction pattern and the edge segment at a coordinate (x_{II,i}, y_{II,i}).

5. The optimal near-field generation method of claim 2, wherein the obtaining the complex near-field comprises:
generating a blurred binary layout by convoluting a skewed Gaussian kernel based on an incident direction of the incident light with the binary layout; and
forming the complex near-field by linearly combining the blurred binary layout with the mutual interference complex diffraction pattern.

6. The optimal near-field generation method of claim 5, wherein the obtaining of the optimal near-field comprises
optimizing the complex near-field through a backpropagation process using a gradient descent algorithm to minimize a value of a loss function indicating a difference between the complex near-field and the rigorous near-field of a design layout.

7. The optimal near-field generation method of claim 1, wherein the artificial neural network comprises at least one of a multilayer perceptron model or a convolutional neural network model.

8. An optimal near-field generation method comprising:
obtaining a mutual interference complex diffraction pattern of a design layout for a target pattern, the mutual interference complex diffraction pattern representing a pattern formed by mutual interference between a plurality of spherical waves formed as a plane wave incident at an angle with respect to each of a plurality of edge segments of the design layout is scattered on each of the plurality of edge segments;
obtaining a complex near-field by reflecting, to the mutual interference complex diffraction pattern, a mask three-dimensional (3D) effect that changes depending on a direction in which the plane wave is incident to the plurality of edge segments;
obtaining a corrected near-field generation by correcting the complex near-field using a Volterra series on an error, the error based on a difference between the complex near-field and a rigorous near-field of the design layout; and
obtaining an optimal near-field by reducing a difference between the complex near-field and the rigorous near-field of the design layout using an artificial neural network.

9. The optimal near-field generation method of claim 8, wherein the obtaining of the mutual interference complex diffraction pattern comprises:
converting the design layout into a binary layout;
extracting an edge of the binary layout;
forming a plurality of edge segments by differentiating the edge;
generating a first complex diffraction pattern formed by the plurality of spherical waves as the plane wave incident to a certain angle, with respect to the plurality of edge segments, is scattered on the plurality of edge segments; and
obtaining the mutual interference complex diffraction pattern formed by mutual interference between the first complex diffraction patterns.

10. The optimal near-field generation method of claim 9, wherein the first complex diffraction pattern Iᵢ(xᵢ, yᵢ) is generated using Equation (1),
$${I}_{i} ( {x}_{i} , {y}_{i} ) = u ( {x}_{i} , {y}_{i} ) \cdot exp ( j ( {k}_{x} \cdot ( x - {x}_{i} ) + {k}_{y} \cdot ( y - {y}_{i} ) ) ) \frac{exp ( \text{?} \cdot \text{?} ) \cdot {thk}_{film}}{\text{?}} exp ( - {α}_{eff} \cdot \text{?} ) , \qquad Equation ( 1 )$$
$$\text{?} \text{indicates text missing or illegible when filed}$$
wherein u(xᵢ, yᵢ) represents a window function,
j represents an imaginary singular number,
kₓ represents an x component of an incident direction vector of the plane wave,
k_{y} represents a y component of an incident direction vector of the plane wave,
k₀ represents an angular wave number,
rᵢ represents a distance between the edge segment and the first complex diffraction pattern,
thk_{film} represents a thickness of a mask, and
α_{eff} represents an effective light absorption coefficient.

11. The optimal near-field generation method of claim 10, wherein the mutual interference complex diffraction pattern I(x, y) is generated using Equation (2),
$$I ( x , y ) = \text{?} {I}_{i} ( {x}_{i} , {y}_{i} ) \cdot {ds}_{1} + \text{?} ( x , y ) I ( x , y ) = \text{?} {I}_{i} ( {x}_{i} , {y}_{i} ) \cdot {ds}_{1} + \text{?} ( x , y ) , \qquad Equation ( 2 )$$
$$\text{?} \text{indicates text missing or illegible when filed}$$
wherein I_{II}(x, y) is a second-order diffraction contribution that is generated using Equation (3),
$$\text{?} ( x , y ) = \text{?} ( C \cdot \text{?} exp ( \text{?} ( \text{?} \cdot ( \text{?} - \text{?} ) + \text{?} \cdot ( \text{?} - \text{?} ) ) ) \frac{\text{?}}{\text{?}} \cdot \text{?} ) \frac{\text{?}}{\text{?}} \cdot exp ( - {α}_{eff} \cdot \text{?} ) \cdot \text{?} , \qquad Equation ( 3 )$$
$$\text{?} \text{indicates text missing or illegible when filed}$$
wherein x_{I,i} and x_{II,j} represent x coordinates of the edge segments different from each other,
y_{I,i} and y_{II,j} represent y coordinates of the edge segments different from each other,
rᵢ represents a distance between the first complex diffraction pattern and the edge segment at a coordinate (x_{I,i}, y_{I,i}), and
rⱼ represents a distance between the first complex diffraction pattern and the edge segment at a coordinate (x_{II,i}, y_{II,i}).

12. The optimal near-field generation method of claim 9, wherein the obtaining of the complex near-field comprises:
generating a blurred binary layout by convoluting a skewed Gaussian kernel based on an incident direction of incident light with the binary layout; and
forming the complex near-field by linearly combining the blurred binary layout with the mutual interference complex diffraction pattern.

13. The optimal near-field generation method of claim 12, wherein the obtaining of the corrected near-field comprises:
obtaining a plurality of features of the design layout using a level set of the design layout and a normal vector field of the design layout;
obtaining a linear error correction model by configuring a first-order Volterra series using the plurality of features of the design layout and a Gauss-Laguerre kernel; and
obtaining a linearly corrected near-field by applying the linear error correction model to the complex near-field, and
wherein the linear error correction model E^{lin}(x, y) is generated using Equation (9),
$${E}^{lin} ( x , y ) = \text{?} {c}_{i} \cdot {v}_{1} ( {K}_{i} ( x , y ) \cdot {F}_{i} ( x , y ) ) , \qquad Equation ( 9 )$$
$$\text{?} \text{indicates text missing or illegible when filed}$$
wherein cᵢ represents a fitting constant,
υ₁ represents the first-order Volterra series,
Kᵢ(x, y) represents the Gauss-Laguerre kernel, and
Fᵢ(x, y) represents the plurality of features of the design layout.

14. The optimal near-field generation method of claim 12, wherein the generating of the corrected near-field further comprises:
obtaining a plurality of features of the design layout using a level set of the design layout and a normal vector field of the design layout;
obtaining a non-linear error correction model by configuring a second-order Volterra series using the plurality of features of the design layout and the Gauss-Laguerre kernel; and
generating a non-linearly corrected near-field by applying the non-linear error correction model to the complex near-field, and
wherein the non-linear error correction model E^{non-lin}(x, y) is generated using Equation (10),
$${E}^{nonlin} ( x , y ) = \text{?} {c}_{mn} \cdot {v}_{2} ( {K}_{mn} ( x , y ) , \text{?} ( x , y ) , {F}_{m} ( x , y ) , {F}_{n} ( x , y ) ) , \qquad Equation ( 10 )$$
$$\text{?} \text{indicates text missing or illegible when filed}$$
wherein cₘₙ represents a fitting constant,
υ₂ represents the second-order Volterra series,
Kₘₙ(x, y) represents the Gauss-Laguerre kernel, and
Fₘ(x, y) and Fₙ(x, y) represent the plurality of features of the design layout.

15. The optimal near-field generation method of claim 12, wherein the obtaining of the optimal near-field comprises
obtaining the optimal near-field by using a gradient descent algorithm to minimize a value of a loss function, the loss function representing a difference between the complex near-field and the rigorous near-field of the design layout, by.

16. A mask manufacturing method comprising:
receiving an input of a design layout for a target pattern;
converting the design layout into a binary layout;
extracting an edge of the binary layout;
forming a plurality of edge segments by differentiating the edge;
obtaining a first complex diffraction pattern, the first complex diffraction pattern representing a pattern formed by a spherical wave formed as a plane wave incident at an angle with respect to the plurality of edge segments is scattered on the plurality of edge segments;
obtaining a mutual interference complex diffraction pattern, the mutual interference complex diffraction pattern representing a pattern formed by mutual interference between the first complex diffraction patterns;
obtaining a complex near-field by reflecting, to the mutual interference complex diffraction pattern, a mask three-dimensional (3D) effect that changes depending on a direction in which the plane wave is incident to the plurality of edge segments;
obtaining a corrected near-field by correcting an error, the error based on a difference between the complex near-field and a rigorous near-field of the design layout;
obtaining an optimal near-field by reducing a difference between the corrected near-field and the rigorous near-field of the design layout;
generating an optical proximity correction (OPC) model based on the optimal near-field;
obtaining an OPC-ed design layout by performing a simulation using an OPC model;
transmitting data about the OPC-ed layout as mask tape-out (MTO) design data;
preparing mask data based on the MTO design data; and
exposing a substrate for a mask based on the mask data.

17. The mask manufacturing method of claim 16, wherein the first complex diffraction pattern Iᵢ(xᵢ, yᵢ) is generated using Equation (1),
$${I}_{i} ( {x}_{i} , {y}_{i} ) = u ( {x}_{i} , {y}_{i} ) \cdot exp ( j ( {k}_{x} \cdot ( x - {x}_{i} ) + {k}_{y} \cdot ( y - {y}_{i} ) ) ) \frac{exp ( \text{?} \cdot \text{?} ) \cdot {thk}_{film}}{\text{?}} exp ( - {α}_{eff} \cdot \text{?} ) , \qquad Equation ( 1 )$$
$$\text{?} \text{indicates text missing or illegible when filed}$$
wherein u(xᵢ, yᵢ) represents a window function,
j represents an imaginary singular number,
kₓ represents an x component of an incident direction vector of the plane wave,
k_{y} represents a y component of an incident direction vector of the plane wave,
k₀ represents an angular wave number,
rᵢ represents a distance between the edge segment and the first complex diffraction pattern,
thk_{film} represents a thickness of a mask, and
α_{eff} represents an effective light absorption coefficient,
wherein the mutual interference complex diffraction pattern I(x, y) is generated using Equation (2),
$$I ( x , y ) = \text{?} {I}_{i} ( {x}_{i} , {y}_{i} ) \cdot {ds}_{1} + \text{?} ( x , y ) I ( x , y ) = \text{?} {I}_{i} ( {x}_{i} , {y}_{i} ) \cdot {ds}_{1} + \text{?} ( x , y ) , \qquad Equation ( 2 )$$
$$\text{?} \text{indicates text missing or illegible when filed}$$
wherein I_{II}(x, y) is a second-order diffraction contribution that is generated using Equation (3),
$$\text{?} ( x , y ) = \text{?} ( C \cdot \text{?} exp ( \text{?} ( {k}_{x} \cdot ( \text{?} - \text{?} ) + {k}_{y} \cdot ( \text{?} - \text{?} ) ) ) \frac{\cdot exp ( \text{?} \cdot \text{?} ) \cdot {thk}_{eff}}{\text{?}} \cdot \text{?} ) \cdot \frac{exp ( \text{?} \cdot \text{?} ) \cdot {thk}_{film}}{\text{?}} \cdot exp ( - {α}_{eff} \cdot \text{?} ) \cdot \text{?} , \qquad Equation ( 3 )$$
$$\text{?} \text{indicates text missing or illegible when filed}$$
wherein x_{I,i} and x_{II,j} represent x coordinates of the edge segments different from each other,
y_{I,i} and y_{II,j} represent y coordinates of the edge segments different from each other,
rᵢ represents a distance between the first complex diffraction pattern and the edge segment at a coordinate (x_{I,i}, y_{I,i}), and
rⱼ represents a distance between the first complex diffraction pattern and the edge segment at a coordinate (x_{II,i}, y_{II,i}).

18. The mask manufacturing method of claim 16, wherein the obtaining the complex near-field comprises:
generating a blurred binary layout by convoluting a skewed Gaussian kernel based on an incident direction of incident light with the binary layout; and
forming the complex near-field by linearly combining the blurred binary layout with the mutual interference complex diffraction pattern.

19. The mask manufacturing method of claim 18, wherein the generating of the corrected near-field comprises:
obtaining a plurality of features of a design layout using a level set of the design layout and a normal vector field of the design layout;
obtaining a linear error correction model by configuring a first-order Volterra series using the plurality of features of the design layout and a Gauss-Laguerre kernel; and
obtaining a linearly corrected near-field by applying the linear error correction model to the complex near-field, and
the linear error correction model E^{lin}(x, y) is generated using Equation (9),
$${E}^{lin} ( x , y ) = \text{?} {c}_{i} \cdot {v}_{1} ( {K}_{i} ( x , y ) \cdot {F}_{i} ( x , y ) ) , \qquad Equation ( 9 )$$
$$\text{?} \text{indicates text missing or illegible when filed}$$
wherein cᵢ represents a fitting constant,
υ₁ represents the first-order Volterra series,
Kᵢ(x, y) represents the Gauss-Laguerre kernel, and
Fᵢ(x, y) represents the plurality of features of the design layout.

20. The mask manufacturing method of claim 16, wherein the obtaining of the optimal near-field comprises
obtaining the optimal near-field by using a gradient descent algorithm to minimize a value of a loss function, the loss function indicating a difference between the complex near-field and a rigorous near-field of the design layout, by.
